(19) United States
(12) Patent Application Publication
(10) Pub. No.: US 2023/0343702 A1
(43) Pub. Date: Oct. 26, 2023

(54) ELECTRONIC COMPONENT

(71) Applicant: ROHM CO., LTD., Kyoto-shi (JP)

(72) Inventors: Bungo TANAKA, Kyoto-shi (JP); Kazumasa NISHIO, Kyoto-shi (JP)

(73) Assignee: ROHM CO., LTD., Kyoto-shi (JP)

(21) Appl. No.: 18/347,623

(22) Filed: Jul. 6, 2023

Related U.S. Application Data
(63) Continuation of application No. PCT/JP2021/043701, filed on Nov. 29, 2021.

(30) Foreign Application Priority Data
Jan. 8, 2021 (JP) 2021-002263
Apr. 23, 2021 (JP) 2021-073596

(51) Int. Cl. H01L 23/522; H01L 23/532; H01L 23/00

(52) U.S. Cl. CPC H01L 23/5228; H01L 28/24; H01L 23/53261; H01L 24/05; H01L 2224/05083; H01L 2224/05008; H01L 2224/05022; H01L 2224/05166; H01L 2224/05186; H01L 2924/04941; H01L 2224/05124; H01L 2224/05147; H01L 2224/05138; H01L 2924/0132; H01L 2924/0133; H01L 2924/01014; H01L 2224/05548; H01L 2224/05566; H01L 2224/05582; H01L 2224/05666; H01L 2224/05686; H01L 2224/05567

(57) ABSTRACT

An electronic component includes a chip that has a main surface, an insulating layer that is laminated at a thickness exceeding 2200 nm on the main surface and has a first end on the chip side and a second end on an opposite side to the chip, and a resistive film that is arranged inside the insulating layer such as not to be positioned within a thickness range of less than 2200 nm on a basis of the first end and includes an alloy crystal constituted of a metal element and a nonmetal element.

### CROSS REFERENCE TO RELATED APPLICATIONS

The present application is a bypass continuation of International Patent Application No. PCT/JP2021/043701, filed on Nov. 29, 2021, which claims priority to Japanese Patent Application No. 2021-002263, filed on Jan. 8, 2021, and Japanese Patent Application No. 2021-073596 filed on Apr. 23, 2021, the entire disclosures of these applications are incorporated herein by reference.

### BACKGROUND OF THE INVENTION

### 1. Field of the Invention

The present invention relates to an electronic component.

### 2. Description of the Related Art

WO 2006/035377 discloses an integrated SiCr metal thin film resistor that includes a dielectric substrate and an SiCr film that is formed on the dielectric substrate.

### BRIEF DESCRIPTION OF THE DRAWINGS

FIG. 1 is a schematic plan view showing an electronic component according to a first embodiment.

FIG. 2 is a sectional view showing a sectional structure along line II-II shown in FIG. 1 together with a resistive film according to a first configuration example.

FIG. 3 is an enlarged view of a region III shown in FIG. 2.

FIG. 4 is a sectional view showing the sectional structure along line II-II shown in FIG. 1 together with the resistive film according to a second configuration example.

FIG. 5 is a sectional view showing the sectional structure along line II-II shown in FIG. 1 together with the resistive film according to a third configuration example.

FIG. 6 is a sectional view showing the sectional structure along line II-II shown in FIG. 1 together with the resistive film according to a fourth configuration example.

FIG. 7 is a graph showing sheet resistances of the resistive films.

FIG. 8 is a graph showing first order coefficients of temperature coefficients of resistance of the resistive films.

FIG. 9 is a graph showing second order coefficients of the temperature coefficients of resistance of the resistive films.

FIG. 10 corresponds to FIG. 2 and is a sectional view showing an electronic component according to a second embodiment (=an embodiment with which a placement location and a connection mode of the resistive film in the electronic component according to the first embodiment are changed).

FIG. 11 corresponds to FIG. 2 and is a sectional view showing an electronic component according to a third embodiment (=an embodiment with which the connection mode of the resistive film in the electronic component according to the first embodiment is changed).

FIG. 12 corresponds to FIG. 2 and is a sectional view showing an electronic component according to a fourth embodiment (=an embodiment with which the placement location and the connection mode of the resistive film in the electronic component according to the third embodiment are changed).

FIG. 13 corresponds to FIG. 2 and is a sectional view showing an electronic component according to a fifth embodiment (=an embodiment with which a form of an insulating region in the electronic component according to the first embodiment is changed).

FIG. 14 is a schematic plan view showing an electronic component according to a sixth embodiment.

FIG. 15 is an enlarged view showing a region XV shown in FIG. 14 together with the resistive film according to a first pattern.

FIG. 16 is a sectional view taken along line XVI-XVI shown in FIG. 15.

FIG. 17 is a sectional view taken along line XVII-XVII shown in FIG. 15.

FIG. 18A is an enlarged view showing the region XV shown in FIG. 14 together with the resistive film according to a second pattern.

FIG. 18B is an enlarged view showing the region XV shown in FIG. 14 together with the resistive film according to a third pattern.

FIG. 18C is an enlarged view showing the region XV shown in FIG. 14 together with the resistive film according to a fourth pattern.

FIG. 19 is a graph showing the sheet resistance of the resistive film shown in FIG. 15.

FIG. 20 is a graph showing the first order coefficient of temperature coefficient of resistance of the resistive film shown in FIG. 15.

FIG. 21 is a graph showing the second order coefficient of the temperature coefficient of resistance of the resistive film shown in FIG. 15.

### DETAILED DESCRIPTION OF THE PREFERRED EMBODIMENTS

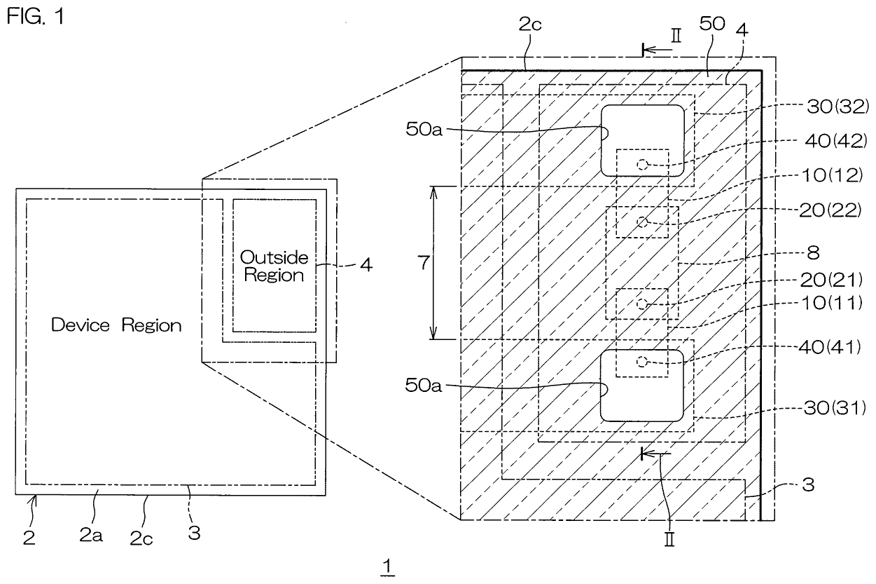

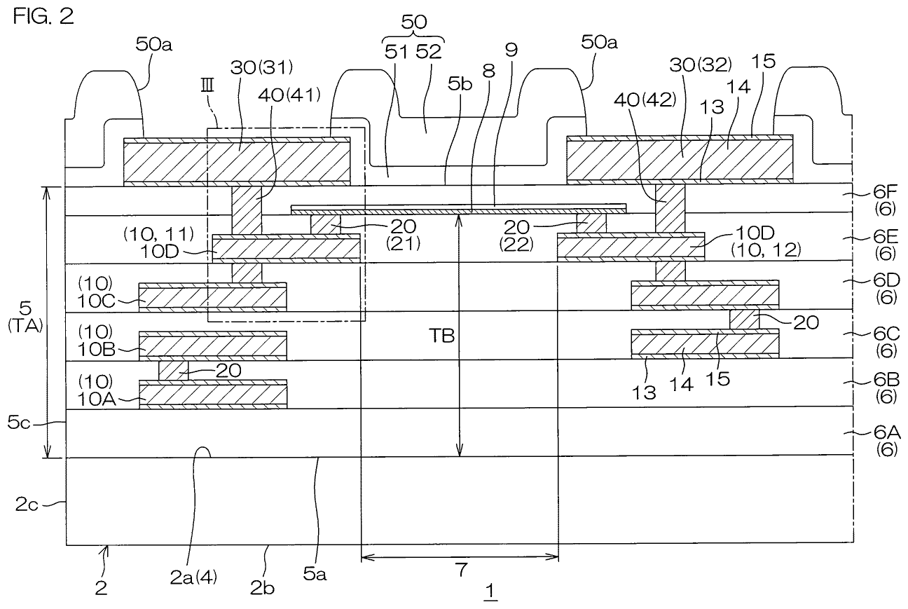

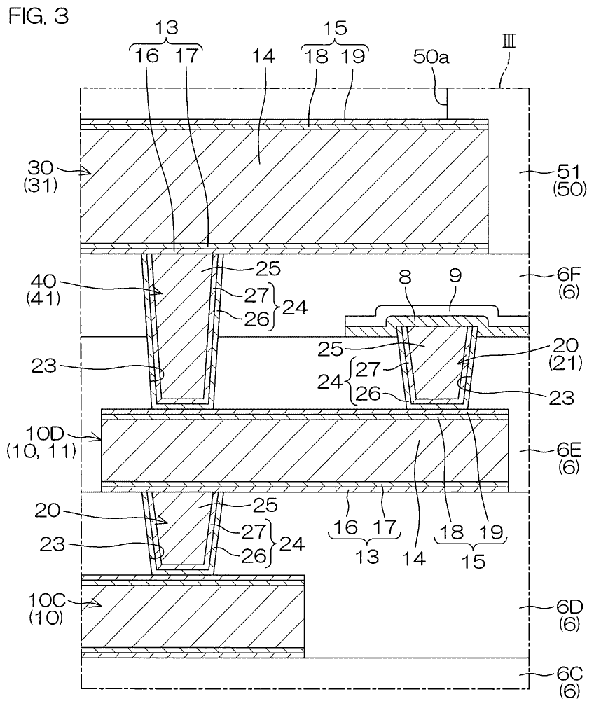

The attached drawings are schematic views and are not drawn precisely and not necessarily matched in scale, etc. FIG. 1 is a schematic plan view showing an electronic component 1 according to a first embodiment. FIG. 2 is a sectional view showing a sectional structure along line II-II shown in FIG. 1 together with a resistive film 8 according to a first configuration example. FIG. 3 is an enlarged view of a region III shown in FIG. 2.

Referring to FIG. 1 to FIG. 3, the electronic component 1 in this embodiment is a semiconductor device that includes any of various functional devices that make use of properties of a semiconductor. The electronic component 1 includes a semiconductor chip 2 (chip) that is formed in a rectangular parallelepiped shape. The semiconductor chip 2 has a comparatively high first thermal conductivity K1. The semiconductor chip 2 may be constituted of an Si (silicon) chip or a WBG (wide band gap) semiconductor chip. A WBG semiconductor is a semiconductor having a bandgap that exceeds a bandgap of Si.

The WBG semiconductor chip may be constituted of an SiC chip, a GaN chip, or a GaAs chip. In this embodiment, the semiconductor chip 2 is constituted of an Si chip and has the first thermal conductivity K1 (≈160 Wm·K) due to Si. The semiconductor chip 2 has a first main surface 2a on one side, a second main surface 2b on another side, and a side surface 2c that is connected to the first main surface 2a and the second main surface 2b. The first main surface 2a and the second main surface 2b are formed in quadrilateral shapes in a plan view of viewing from a normal direction thereto.

The electronic component 1 includes a device region 3 that is provided in the first main surface 2a. The device region 3 is demarcated in an inner portion of the first main surface 2a at intervals from the side surface 2c in plan view. The number, placement, and shape of the device region 3 are arbitrary and not restricted to a specific number, placement, and shape. The electronic component 1 includes a functional device that is formed in the device region 3. The functional device may include at least one among a semiconductor switching device, a semiconductor rectifying device, and a passive device.

The semiconductor switching device may include at least one among a JFET (junction field effect transistor), a MISFET (metal insulator semiconductor field effect transistor), a BJT (bipolar junction transistor), and an IGBT (insulated gate bipolar junction transistor).

The semiconductor rectifying device may include at least one among a pn-junction diode, a pin-junction diode, a Zener diode, a Schottky barrier diode, and a fast recovery diode. The passive device may include at least one among a resistor, a capacitor, an inductor, and a fuse. The functional device may include a circuit network (for example, an integrated circuit such as an LSI, etc.) in which at least two devices among a semiconductor switching device, a semiconductor rectifying device, and a passive device are selectively combined.

The electronic component 1 includes an outside region 4 that is provided in the first main surface 2a. The outside region 4 is a region outside the device region 3. The outside region 4 is a region in which a functional device is not included in the first main surface 2a and is demarcated in an arbitrary shape and an arbitrary number at an arbitrary position in the first main surface 2a. In this embodiment, the outside region 4 is demarcated in a region of the first main surface 2a between the side surface 2c and the device region 3. If a plurality of the device regions 3 are demarcated in the first main surface 2a, the outside region 4 may be demarcated in a region between the plurality of device regions 3.

The electronic component 1 includes an insulating layer 5 that is laminated on the first main surface 2a. The insulating layer 5 covers the device region 3 and the outside region 4. That is, the insulating layer 5 has a region that covers the functional device and a region that does not cover any functional device. The insulating layer 5 has a second thermal conductivity K2 that is less than the first thermal conductivity K1 of the semiconductor chip 2 (K1<K2). That is, the insulating layer 5 has a high heat storage property in comparison to the semiconductor chip 2.

The insulating layer 5 includes at least one of silicon oxide and silicon nitride. That is, the insulating layer 5 has the second thermal conductivity K2 due to at least one of a thermal conductivity due to silicon oxide (≈1.3 Wm·K) and a thermal conductivity due to silicon nitride (≈29.3 Wm·K). In this embodiment, the insulating layer 5 is constituted of silicon oxide and has the second thermal conductivity K2 due to silicon oxide (≈1.3 Wm·K).

The insulating layer 5 has a first end 5a on one side in a thickness direction (semiconductor chip 2 side), a second end 5b on another side in the thickness direction (side opposite to the semiconductor chip 2), and an insulating side surface 5c that is connected to the first end 5a and the second end 5b. The first end 5a is connected to the semiconductor chip 2 (first main surface 2a). The second end 5b is formed flat such as to extend substantially parallel to the first main surface 2a and is formed in a quadrilateral shape matching the first main surface 2a in plan view. The insulating side surface 5c extends from a peripheral edge of the second end 5b toward the semiconductor chip 2 side and is continuous to the side surface 2c of the semiconductor chip 2.

The insulating layer 5 has a predetermined thickness TA. The thickness TA is a distance between the first end 5a and the second end 5b. The thickness TA exceeds 2200 nm. An upper limit value of the thickness TA is adjusted according to specifications of the functional device and is set to a value that would not present a problem in terms of a forming process time of the insulating layer 5. The thickness TA may have an upper limit value of any one of not more than 30000 nm, not more than 25000 nm, not more than 20000 nm, not more than 15000 nm, not more than 10000 nm, and not more than 5000 nm. The thickness TA is preferably set to not less than 3000 nm and not more than 10000 nm. In this embodiment, the thickness TA is set to 4500 nm.

The insulating layer 5 has a laminated structure including a plurality of interlayer insulating films 6 that are laminated on the first main surface 2a. The plurality of interlayer insulating films 6 are laminated on the first main surface 2a by a CVD (chemical vapor deposition) method. As long as the insulating layer 5 has the thickness TA (2200 nm<TA), the number of laminated layers of the interlayer insulating films 6 is arbitrary and not restricted to a specific number of laminated layers. The number of laminated layers of the interlayer insulating films 6 is set to a typical value that would not present a problem in terms of the forming process time of the insulating layer 5. The number of laminated layers of the interlayer insulating films 6 may, for example, be not less than 2 and not more than 25. The number of laminated layers of the interlayer insulating films 6 is preferably not less than 2 and not more than 10.

The insulating layer 5 preferably has the laminated structure that includes not less than three layers of the interlayer insulating films 6. The insulating layer 5 especially preferably has the laminated structure that includes not less than four layers of the interlayer insulating films 6. In this embodiment, the insulating layer 5 has the laminated structure that includes six layers of the interlayer insulating films 6. The six layers of the interlayer insulating films 6 include a first interlayer insulating film 6A, a second interlayer insulating film 6B, a third interlayer insulating film 6C, a fourth interlayer insulating film 6D, a fifth interlayer insulating film 6E, and a sixth interlayer insulating film 6F in that order from the first main surface 2a side.

The plurality of interlayer insulating films 6 may each include at least one of a silicon oxide film and a silicon nitride film. In this embodiment, the plurality of interlayer insulating films 6 each has a single layer structure constituted of a silicon oxide film. The insulating layer 5 constituted of silicon oxide is thereby arranged. The plurality of interlayer insulating films 6 may each have a thickness of not less than 100 nm and not more than 3000 nm. Preferably, the plurality of interlayer insulating films 6 each have a thickness of not less than 300 nm and not more than 1500 nm. The plurality of interlayer insulating films 6 may have mutually different thicknesses or may have a mutually equal thickness.

The electronic component 1 has an insulating region 7 that is formed in an arbitrary region inside the insulating layer 5. The insulating region 7 is a region that does not have a conductor film (a metal film, etc.) in a thickness direction of the insulating layer 5 and has only an insulator. In this embodiment, the insulating region 7 is formed in a portion that covers the outside region 4 in the insulating layer 5. That is, the insulating region 7 covers the outside region 4 outside the device region 3 and does not cover any functional device. In other words, the functional device is not formed below the insulating region 7.

In this embodiment, the insulating region 7 is formed toward the second end 5b with the first end 5a (first main surface 2a) as a basis (zero point) and up to a thickness direction intermediate portion of the insulating layer 5. In this embodiment, the insulating region 7 has a laminated structure constituted of a portion of the plurality of interlayer insulating films 6 (in this embodiment, the first to fifth interlayer insulating films 6A to 6E).

The insulating region 7 has a predetermined insulating thickness TB in the thickness direction of the insulating layer 5. The insulating thickness TB is set to not less than 2200 nm. An upper limit value of the insulating thickness TB is less than the thickness TA of the insulating layer 5 (TB<TA). The insulating thickness TB may have an upper limit value of any one of less than 30000 nm, not more than 25000 nm, not more than 20000 nm, not more than 15000 nm, not more than 10000 nm, and not more than 5000 nm. If the thickness TA of the insulating layer 5 exceeds 3100 nm, the insulating thickness TB is preferably set to not less than 3100 nm. In this embodiment, the insulating thickness TB is set to 3900 nm.

The electronic component 1 includes the resistive film 8 that is arranged inside the insulating layer 5. The resistive film 8 is a so-called thin film resistor. The resistive film 8 includes an alloy crystal constituted of a metal element and a nonmetal element. The resistive film 8 is formed through a sputtering step and a crystallizing step. In the sputtering step, an alloy including the metal element and the nonmetal element is applied onto the interlayer insulating film 6 that is a film forming object by a sputtering method. A base alloy film that is to be a base of the resistive film 8 is thereby formed on the interlayer insulating film 6 that is the film forming object. The base alloy film immediately after film forming is in an amorphous state.

In the crystallizing step, the base alloy film is heated at a temperature (for example, a temperature of not less than 300° C. and not more than 500° C.) and for a time at and by which the base alloy film crystallizes. The resistive film 8 constituted of an alloy crystal film is thereby formed. The crystallization temperature and crystallization time of the base alloy film are set to a temperature and a time that would not present a problem in terms of electrical characteristics of the functional device. A sheet resistance Rs of the resistive film 8 is established by a sheet resistance Rs of the alloy crystal film formed through the crystallizing step.

The type of alloy crystal constituting the resistive film 8 is arbitrary as long as the crystallizing step is performed. The resistive film 8 may, for example, include at least one among a CrSi film, a CrSiN film, a CrSiO film, a TaN film, and a TiN film. In this embodiment, the resistive film 8 has a single layer structure constituted of a CrSi film. The resistive film 8 may be referred to as a “CrSi resistive film.” A content of the metal (Cr) with respect to a total weight of the resistive film 8 (CrSi film) may be not less than 5 wt % and not more than 50 wt %.

The resistive film 8 may have a thickness of not less than 0.1 nm and not more than 100 nm. A lower limit value of the thickness of the resistive film 8 is preferably not less than 0.5 nm. The lower limit value of the thickness of the resistive film 8 is most preferably not less than 1 nm. An upper limit value of the thickness of the resistive film 8 is preferably not more than 10 nm. The upper limit value of the thickness of the resistive film 8 is most preferably not more than 5 nm. The sheet resistance Rs may be not less than 100Ω/□ and not more than 50000Ω/□. The sheet resistance Rs of the resistive film 8 is preferably not less than 1000Ω/□ and not more than 10000Ω/□. The sheet resistance Rs is adjusted by adjusting the thickness of the resistive film 8, a planar area of the resistive film 8, the content of the metal, etc.

The resistive film 8 is preferably arranged on the interlayer insulating film 6 of the third layer or higher (any of the third to fifth interlayer insulating films 6C to 6E) and not arranged on either of the interlayer insulating films 6 positioned below the third layer (first and second interlayer insulating films 6A and 6B). The resistive film 8 is especially preferably arranged on the interlayer insulating film 6 of the fourth layer or higher (either of the fourth and fifth interlayer insulating films 6D and 6E) and not arranged on any of the interlayer insulating films 6 positioned below the fourth layer (first to third interlayer insulating films 6A to 6C).

In this embodiment, the resistive film 8 is arranged on the fifth interlayer insulating film 6E and is covered by the sixth interlayer insulating film 6F. Preferably, the resistive film 8 exclusively occupies the interlayer insulating film 6 that is the film forming object (in this embodiment, the fifth interlayer insulating film 6E). That is, preferably, a conductor film (metal film) other than the resistive film 8 is not arranged in the same layer as the resistive film 8.

The resistive film 8 is arranged in a region between the second end 5b and the insulating region 7 and covers the insulating region 7 inside the insulating layer 5. The resistive film 8 preferably covers the insulating region 7 directly. That is, the resistive film 8 is preferably arranged inside the insulating layer 5 such as not to be positioned within a thickness range of less than 2200 nm on a basis of the first end 5a (first main surface 2a). The resistive film 8 is especially preferably arranged inside the insulating layer 5 such as not to be positioned within a thickness range of less than 3100 nm on the basis of the first end 5a (first main surface 2a).

In this embodiment, the resistive film 8 is arranged inside the insulating layer 5 such as not to be positioned within a thickness range of less than 3900 nm on the basis of the first end 5a (first main surface 2a). Preferably, a thickness (insulating thickness TB) between the first end 5a (first main surface 2a) and the resistive film 8 inside the insulating layer 5 is not less than a thickness between the second end 5b and the resistive film 8 inside the insulating layer 5. In this embodiment, the insulating thickness TB exceeds the thickness between the second end 5b and the resistive film 8.

The resistive film 8 faces the first main surface 2a across the insulating region 7. That is, the resistive film 8 includes a portion that faces the first main surface 2a across a region in which a conductor film (metal film) is not arranged inside the insulating layer 5. Also, the resistive film 8 includes a portion that faces the outside region 4 across the insulating region 7 and does not face any functional device. In this embodiment, the resistive film 8 does not face any functional device in the thickness direction of the insulating layer 5. A planar shape of the resistive film 8 is arbitrary. The resistive film 8 may have, in plan view, a quadrilateral shape, a rectangular shape (band shape), a polygonal shape, a meandering shape (zigzag shape), or a shape in which the above shapes are combined selectively.

The electronic component 1 includes an inorganic insulating film 9 that covers the resistive film 8 inside the insulating layer 5. The inorganic insulating film 9 is interposed in a region between the resistive film 8 and any of the interlayer insulating films 6 (in this embodiment, the sixth interlayer insulating film 6F) and faces the insulating region 7 across the resistive film 8. The inorganic insulating film 9 preferably covers an entire area of the resistive film 8. In this embodiment, the inorganic insulating film 9 has a planar shape matching the planar shape of the resistive film 8. The inorganic insulating film 9 may include at least one of a silicon oxide film and a silicon nitride film. In this embodiment, the inorganic insulating film 9 has a single layer structure constituted of a silicon oxide film.

The electronic component 1 includes a plurality of interlayer wirings 10 that are laminated and arranged within a thickness range between the first end 5a and the second end 5b inside the insulating layer 5. The plurality of interlayer wirings 10 are each electrically connected to the corresponding functional device and/or resistive film 8. The plurality of interlayer wirings 10 may electrically connect a plurality of functional devices to each other. The plurality of interlayer wirings 10 may each electrically connect the resistive film 8 to an arbitrary functional device. Placement locations and modes of routing of the plurality of interlayer wirings 10 are arbitrary.

In this embodiment, the plurality of interlayer wirings 10 are laminated and arranged within a thickness range between the first end 5a and the resistive film 8 inside the insulating layer 5 but are not arranged within a thickness range between the second end 5b and the resistive film 8 inside the insulating layer 5. The plurality of interlayer wirings 10 are each arranged on the corresponding interlayer insulating film 6. That is, the plurality of interlayer wirings 10 form a multilayer wiring structure with the plurality of interlayer insulating films 6 and the resistive film 8. The number of laminated layers of the plurality of interlayer wirings 10 is adjusted in accordance with the number of laminated layers of the interlayer insulating films 6. In this embodiment, the plurality of interlayer wirings 10 include at least one first interlayer wiring 10A, at least one second interlayer wiring 10B, at least one third interlayer wiring 10C, and at least one fourth interlayer wiring 10D.

The first interlayer wiring 10A is arranged on the first interlayer insulating film 6A and is covered by the second interlayer insulating film 6B. The second interlayer wiring 10B is arranged on the second interlayer insulating film 6B and is covered by the third interlayer insulating film 6C. The third interlayer wiring 10C is arranged on the third interlayer insulating film 6C and is covered by the fourth interlayer insulating film 6D. The fourth interlayer wiring 10D is arranged on the fourth interlayer insulating film 6D and is covered by the fifth interlayer insulating film 6E. The plurality of interlayer wirings 10 are not arranged on the interlayer insulating film 6 on which the resistive film 8 is arranged (in this embodiment, the fifth interlayer insulating film 6E).

The plurality of interlayer wirings 10 include a first lower wiring 11 and a second lower wiring 12 for the resistive film 8. The first lower wiring 11 is arranged directly below one end of the resistive film 8. The one end of the resistive film 8 signifies an electrical end connection. In this embodiment, the first lower wiring 11 is constituted of one of the fourth interlayer wirings 10D. The first lower wiring 11 is arranged along the insulating region 7 such as to demarcate the insulating region 7 in plan view.

The second lower wiring 12 is arranged directly below another end of the resistive film 8. The other end of the resistive film 8 signifies an electrical end connection. The second lower wiring 12 is arranged at an interval from the first lower wiring 11 in the same layer as the first lower wiring 11. In this embodiment, the second lower wiring 12 is constituted of one of the fourth interlayer wirings 10D. The second lower wiring 12 is arranged along the insulating region 7 such as to demarcate the insulating region 7 in plan view. The second lower wiring 12 faces the first lower wiring 11 across the insulating region 7 in plan view. In such a structure, the resistive film 8 is arranged inside the insulating layer 5 such as to cover the insulating region 7 and overlap with the first lower wiring 11 and the second lower wiring 12 in plan view.

The plurality of interlayer wirings 10 each have a thickness that exceeds the thickness of the resistive film 8. The plurality of interlayer wirings 10 each have a laminated structure including a first barrier film 13, a main body film 14, and a second barrier film 15 that are laminated in that order from the semiconductor chip 2 side. The first barrier film 13 is constituted of a Ti-based metal film. The first barrier film 13 may have a laminated structure including a Ti film 16 and a TiN film 17 that are laminated in that order from the semiconductor chip 2 side.

The main body film 14 is constituted of an Al-based metal film or a Cu-based metal film and has a thickness exceeding a thickness of the first barrier film 13. The main body film 14 may include at least one among a pure Al film (an Al film with a purity of not less than 99%), a pure Cu film (an Cu film with a purity of not less than 99%), an AlCu alloy film, an AlSi alloy film, and an AlSiCu alloy film. The second barrier film 15 is constituted of a Ti-based metal film and has a thickness less than the thickness of the main body film 14. The second barrier film 15 may have a laminated structure including a Ti film 18 and a TiN film 19 that are laminated in that order from the main body film 14 side.

The electronic component 1 includes a plurality of via electrodes 20 that are arranged inside the insulating layer 5. The plurality of via electrodes 20 are each electrically connected to two arbitrary interlayer wirings that face each other in the thickness direction. The plurality of via electrodes 20 include a first via electrode 21 and a second via electrode 22 for the resistive film 8. The first via electrode 21 is interposed between the one end of the resistive film 8 and the first lower wiring 11 and is electrically connected to the one end of the resistive film 8 and the first lower wiring 11. The second via electrode 22 is interposed between the other end of the resistive film 8 and the second lower wiring 12 and is electrically connected to the other end of the resistive film 8 and the second lower wiring 12.

An upper end portion of the first via electrode 21 and an upper end portion of the second via electrode 22 may project from a main surface of the corresponding interlayer insulating film 6 (in this embodiment, the main surface of the fifth interlayer insulating film 6E). In this case, the resistive film 8 may be formed as a film along the upper end portion (a main surface and a portion of a side wall) of the first via electrode 21 and the upper end portion (a main surface and a portion of a side wall) of the second via electrode 22 and may have raised portions due to the upper end portion of the first via electrode 21 and the upper end portion of the second via electrode 22.

The plurality of via electrodes 20 each have a laminated structure including a via barrier film 24 and a via main body 25 that are laminated in that order from an inner wall of a via hole 23 formed in the corresponding interlayer insulating film 6. The via barrier film 24 is formed as a film along the inner wall of the via hole 23 and demarcates a recess inside the via hole 23. The via barrier film 24 is constituted of a Ti-based metal film. The via barrier film 24 may have a laminated structure including a Ti film 26 and a TiN film 27 that are laminated in that order from the inner wall of the via hole 23. The via main body 25 is embedded in the via hole 23 across the via barrier film 24. The via main body 25 includes W (tungsten) or Cu (copper) that is embedded as an integrated member in the via hole 23.

The electronic component 1 includes a plurality of top wirings 30 that are arranged on the second end 5b of the insulating layer 5. The plurality of top wirings 30 are each electrically connected to the corresponding functional device and/or resistive film 8. The plurality of top wirings 30 are terminal electrodes that are connected to lead wires (for example, bonding wires). The plurality of top wirings 30 transmit input signals from an exterior to respective functional devices or transmit output signals from the respective functional devices to the exterior.

The plurality of top wirings 30 include a first upper wiring 31 and a second upper wiring 32 for the resistive film 8. The first upper wiring 31 is arranged directly above the first lower wiring 11. The second upper wiring 32 is arranged directly above the second lower wiring 12. The plurality of top wirings 30 have a thickness that exceeds the thickness of the plurality of interlayer wirings 10. As with the plurality of interlayer wirings 10, the plurality of top wirings 30 each have the laminated structure including the first barrier film 13, the main body film 14, and the second barrier film 15 that are laminated in that order from the semiconductor chip 2 side (insulating layer 5 side).

The electronic component 1 includes a plurality of long via electrodes 40 that are arranged inside the insulating layer 5. The plurality of long via electrodes 40 are each electrically connected to an arbitrary one of the interlayer wiring 10 and an arbitrary one of the top wiring 30 that face each other in the thickness direction. The long via electrodes 40 are via electrodes 20, among the via electrodes 20, that each extend across at least two interlayer insulating films 6.

The plurality of long via electrodes 40 include a first long via electrode 41 and a second long via electrode 42 for the resistive film 8. The first long via electrode 41 is interposed in a region between the first lower wiring 11 and the first upper wiring 31 and is electrically connected to the first lower wiring 11 and the first upper wiring 31. The first long via electrode 41 is arranged at an interval from the resistive film 8 and extends from the second end 5b toward the first end 5a side such as to traverse the resistive film 8.

The second long via electrode 42 is interposed in a region between the second lower wiring 12 and the second upper wiring 32 and is electrically connected to the second lower wiring 12 and the second upper wiring 32. The second long via electrode 42 is arranged at an interval from the resistive film 8 and extends from the second end 5b side toward the first end 5a side such as to traverse the resistive film 8. As with the plurality of via electrodes 20, the plurality of long via electrodes 40 each have the laminated structure including the via barrier film 24 and the via main body 25 that are laminated in that order from the inner wall of the via hole 23 formed in the corresponding interlayer insulating film 6.

The electronic component 1 includes a top insulating layer 50 that partially covers the plurality of top wirings 30 on the second end 5b of the insulating layer 5. The top insulating layer 50 may be referred to as a “passivation layer.” The top insulating layer 50 has a plurality of pad openings 50a that partially expose inner portions of the plurality of top wirings 30 and covers peripheral edge portions of the plurality of top wirings 30.

In this embodiment, the top insulating layer 50 has a laminated structure that includes a first insulating film 51 and a second insulating film 52 that are laminated in that order from the insulating layer 5 side. The first insulating film 51 may include a silicon oxide film. The second insulating film 52 includes an insulator different from the first insulating film 51. The second insulating film 52 may include a nitride silicon film. The top insulating layer 50 may have a single layer structure that is constituted of the first insulating film 51 or the second insulating film 52.

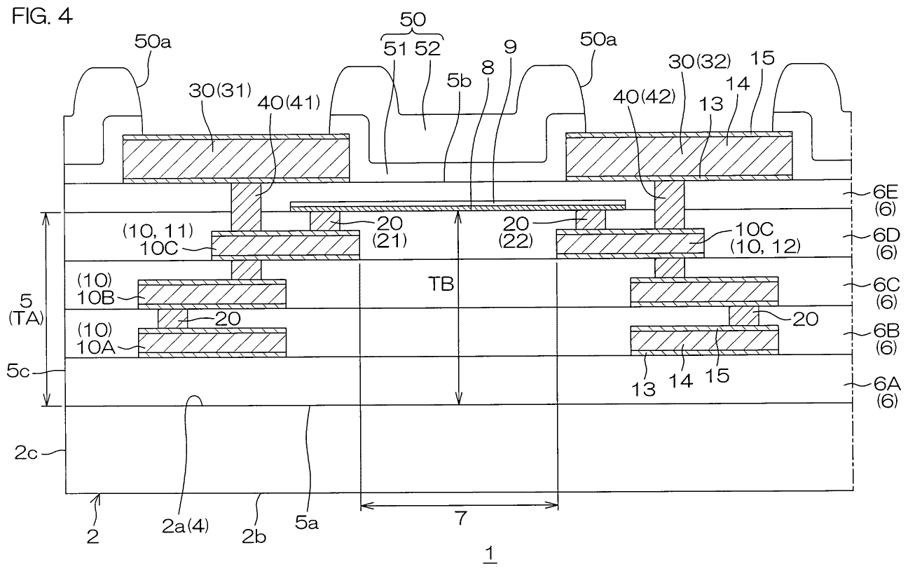

FIG. 4 is a sectional view showing the sectional structure along line II-II shown in FIG. 1 together with the resistive film 8 according to a second configuration example. In the following, structures corresponding to structures shown in FIG. 1 to FIG. 3 are provided with the same reference signs and description thereof shall be omitted.

Referring to FIG. 4, in this configuration, the insulating layer 5 includes the first to fifth interlayer insulating films 6A to 6E that are laminated in that order from the first main surface 2a side and has the thickness TA of 3600 nm. The insulating region 7 includes a laminated structure that is constituted of a portion of the first to fourth interlayer insulating films 6A to 6D and has the insulating thickness TB of 3100 nm. The resistive film 8 is arranged inside the insulating layer 5 such as not to be positioned within the thickness range of less than 3100 nm on the basis of the first end 5a (first main surface 2a). The plurality of interlayer wirings 10 include the first to third interlayer wirings 10A to 10C. In this configuration, the first lower wiring 11 and the second lower wiring 12 for the resistive film 8 are each constituted of one of the third interlayer wirings 10C.

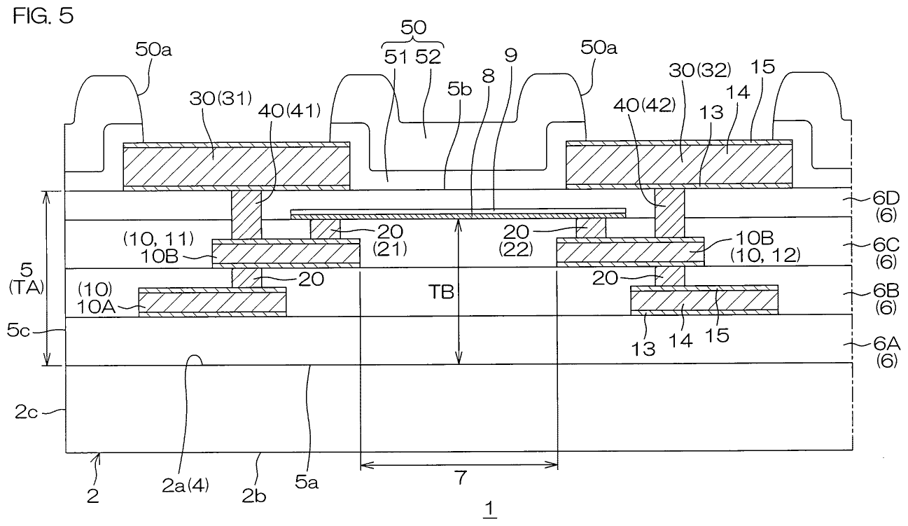

FIG. 5 is a sectional view showing the sectional structure along line II-II shown in FIG. 1 together with the resistive film 8 according to a third configuration example. In the following, structures corresponding to structures shown in FIG. 1 to FIG. 3 are provided with the same reference signs and description thereof shall be omitted.

Referring to FIG. 5, in this configuration, the insulating layer 5 includes the first to fourth interlayer insulating films 6A to 6D that are laminated in that order from the first main surface 2a side and has the thickness TA of 2700 nm. The insulating region 7 includes a laminated structure that is constituted of a portion of the first to third interlayer insulating films 6A to 6C and has the insulating thickness TB of 2200 nm. The resistive film 8 is arranged inside the insulating layer 5 such as not to be positioned within the thickness range of less than 2200 nm on the basis of the first end 5a (first main surface 2a). The plurality of interlayer wirings 10 include the first and second interlayer wirings 10A and 10B. In this configuration, the first lower wiring 11 and the second lower wiring 12 for the resistive film 8 are each constituted of one of the second interlayer wirings 10B.

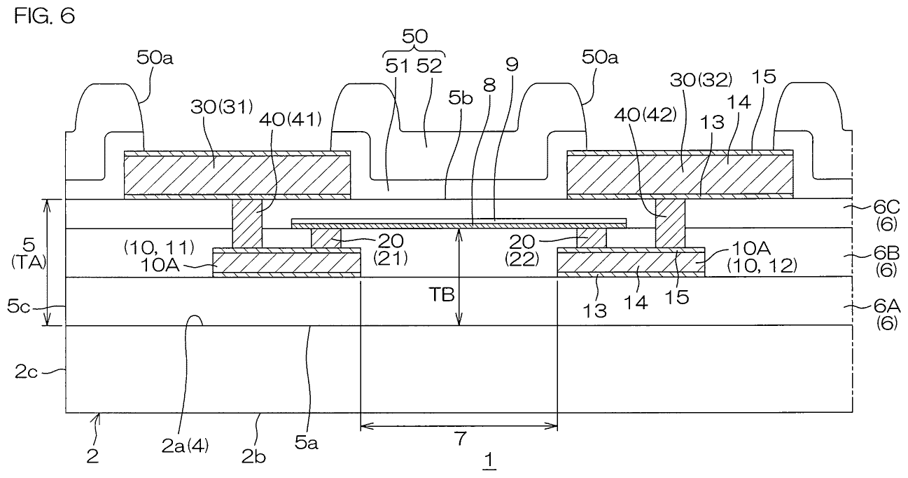

FIG. 6 is a sectional view showing the sectional structure along line II-II shown in FIG. 1 together with the resistive film 8 according to a fourth configuration example. In the following, structures corresponding to structures shown in FIG. 1 to FIG. 3 are provided with the same reference signs and description thereof shall be omitted.

Referring to FIG. 6, in this configuration, the insulating layer 5 includes the first to third interlayer insulating films 6A to 6C that are laminated in that order from the first main surface 2a side and has the thickness TA of 1900 nm. The insulating region 7 includes a laminated structure that is constituted of a portion of the first and second interlayer insulating films 6A and 6B and has the insulating thickness TB of 1400 nm. The resistive film 8 is arranged inside the insulating layer 5 such as not to be positioned within a thickness range of less than 1400 nm on the basis of the first end 5a (first main surface 2a). The plurality of interlayer wirings 10 include the first interlayer wirings 10A. In this configuration, the first lower wiring 11 and the second lower wiring 12 for the resistive film 8 are each constituted of one of the first interlayer wirings 10A.

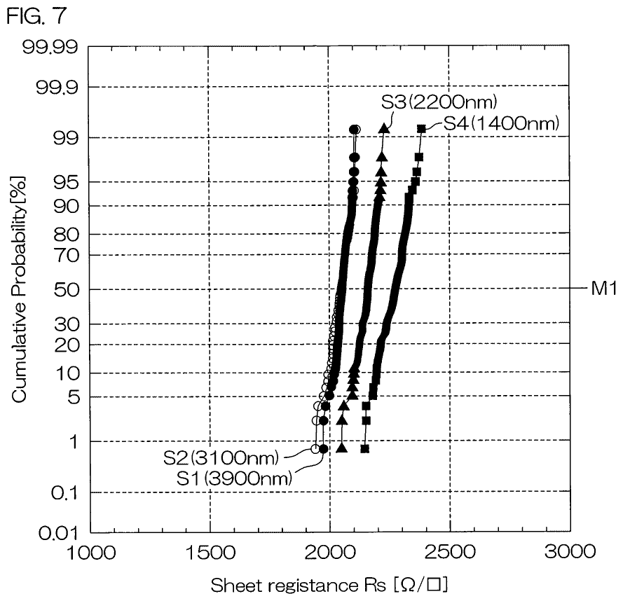

Electrical characteristics of the resistive films 8 according to the first to fourth configuration examples shall now be described with reference to FIG. 7 to FIG. 9. In the following, a description shall be provided on a sheet resistance Rs, a first order coefficient TCR1 of temperature coefficient of resistance (TCR), and a second order coefficient TCR2 of TCR as the electrical characteristics of each resistive film 8. The number of samples of each of the resistive films 8 of the first to fourth configuration examples used to obtain graphs of FIG. 7 to FIG. 9 is 68.

FIG. 7 is a graph showing the sheet resistances Rs of the resistive films 8. In FIG. 7, the ordinate shows a cumulative probability [%] and the abscissa shows the sheet resistance Rs [Ω/□] of the resistive film 8. A first characteristic S1, a second characteristic S2, a third characteristic S3, and a fourth characteristic S4 are shown in FIG. 7.

The first characteristic S1 represents a characteristic of the resistive film 8 according to the first configuration example (insulating thickness TB=3900 nm). The second characteristic S2 represents a characteristic of the resistive film 8 according to the second configuration example (insulating thickness TB=3100 nm).

The third characteristic S3 represents a characteristic of the resistive film 8 according to the third configuration example (insulating thickness TB=2200 nm). The fourth characteristic S4 represents a characteristic of the resistive film 8 according to the fourth configuration example (insulating thickness TB=1400 nm). In all cases, a design value of the sheet resistance Rs is not less than 1700Ω/□ and not more than 2300 Ω/□.

Referring to the first characteristic S1, with the resistive film 8 according to the first configuration example, the sheet resistance Rs falls within a range of not less than 1970Ω/□ and not more than 2110Ω/□ and a median value M1 (50%) of the sheet resistance Rs is approximately 2050Ω/□. Referring to the second characteristic S2, with the resistive film 8 according to the second configuration example, the sheet resistance Rs falls within a range of not less than 1930Ω/□ and not more than 2120Ω/□ and the median value M1 (50%) of the sheet resistance Rs is approximately 2050 Ω/□.

Referring to the third characteristic S3, with the resistive film 8 according to the third configuration example, the sheet resistance Rs falls within a range of not less than 2140Ω/□ and not more than 2230Ω/□ and the median value M1 (50%) of the sheet resistance Rs is approximately 2150Ω/□. Referring to the fourth characteristic S4, with the resistive film 8 according to the fourth configuration example, the sheet resistance Rs falls within a range of not less than 2130Ω/□ and not more than 2390Ω/□ and the median value M1 (50%) of the sheet resistance Rs is approximately 2270 Ω/□.

The sheet resistance Rs is dependent on placement of the resistive film 8 and a precision of the sheet resistance Rs with respect to a design value improves with increase in distance between the first end 5a of the insulating layer 5 and the resistive film 8. Specifically, the precision of the sheet resistance Rs with respect to the design value improves in the order of: the fourth configuration example, the third configuration example, the second configuration example, and the first configuration example. Since the first characteristic S1 and the second characteristic S2 are substantially matched, the sheet resistance Rs has a tendency to converge toward the design value without diverging due to increase in the distance between the first end 5a and the resistive film 8.

From the above results, the resistive film 8 is preferably arranged inside the insulating layer 5 such as not to be positioned within the thickness range of less than 2200 nm on the basis of the first end 5a of the insulating layer 5. With this structure, the precision of the sheet resistance Rs with respect to the design value can be improved. In this case, the resistive film 8 preferably covers the insulating region 7 that has the insulating thickness TB of not less than 2200 nm.

The resistive film 8 especially preferably covers the insulating region 7 that has a thickness of not less than 3100 nm. With this structure, the precision of the sheet resistance Rs with respect to the design value can be improved further. In this case, the resistive film 8 is preferably arranged inside the insulating layer 5 such as not to be positioned within the thickness range of less than 3100 nm on the basis of the first end 5a of the insulating layer 5.

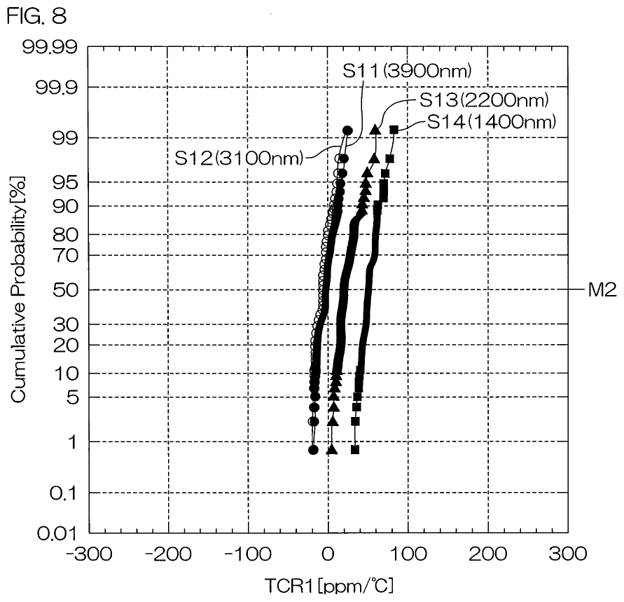

FIG. 8 is a graph showing the first order coefficients TCR1 of the TCRs of the resistive films 8. In FIG. 8, the ordinate shows a cumulative probability [%] and the abscissa shows the first order coefficient TCR1 [ppm/° C.] of the TCR. A first characteristic S11, a second characteristic S12, a third characteristic S13, and a fourth characteristic S14 are shown in FIG. 8.

The first characteristic S11 represents a characteristic of the resistive film 8 according to the first configuration example. The second characteristic S12 represents a characteristic of the resistive film 8 according to the second configuration example. The third characteristic S13 represents a characteristic of the resistive film 8 according to the third configuration example. The fourth characteristic S14 represents a characteristic of the resistive film 8 according to the fourth configuration example. In all cases, a design value of the first order coefficient TCR1 is not less than −100 ppm/° C. and not more than +100 ppm/° C. An optimal value of the first order coefficient TCR1 is 0 ppm/° C.

Referring to the first characteristic S11, with the resistive film 8 according to the first configuration example, the first order coefficient TCR1 falls within a range of not less than −20 ppm/° C. and not more than +25 ppm/° C. and a median value M2 (50%) is substantially 0 ppm/° C. The first order coefficient TCR1 according to the first characteristic S11 falls within a range of not less than −10 ppm/° C. and not more than +10 ppm/° C. in a range of ±20% on a basis of the median value M2 (50%).

Referring to the second characteristic S12, with the resistive film 8 according to the second configuration example, the first order coefficient TCR1 falls within a range of not less than −20 ppm/° C. and not more than +25 ppm/° C. and the median value M2 (50%) is substantially 0 ppm/° C. The first order coefficient TCR1 according to the second characteristic S12 falls within a range of not less than −10 ppm/° C. and not more than +10 ppm/° C. in a range of ±20% on the basis of the median value M2 (50%).

Referring to the third characteristic S13, with the resistive film 8 according to the third configuration example, the first order coefficient TCR1 falls within a range of not less than +5 ppm/° C. and not more than +60 ppm/° C. and the median value M2 (50%) is approximately +21 ppm/° C. Referring to the fourth characteristic S14, with the resistive film 8 according to the fourth configuration example, the first order coefficient TCR1 falls within a range of not less than +34 ppm/° C. and not more than +84 ppm/° C. and the median value M2 (50%) is approximately +52 ppm/° C.

The first order coefficient TCR1 is dependent on the placement of the resistive film 8 and improves with increase in the distance between the first end 5a of the insulating layer 5 and the resistive film 8. Specifically, the first order coefficient TCR1 improves in the order of: the fourth configuration example, the third configuration example, the second configuration example, and the first configuration example. Since the first characteristic S11 and the second characteristic S12 are substantially matched, the first order coefficient TCR1 has a tendency to converge toward the design value without diverging due to increase in the distance between the first end 5a and the resistive film 8.

From the above results, the resistive film 8 is preferably arranged inside the insulating layer 5 such as not to be positioned within the thickness range of less than 2200 nm on the basis of the first end 5a of the insulating layer 5. With this structure, the resistive film 8 having the first order coefficient TCR1 in a range of not less than −20 ppm/° C. and not more than +60 ppm/° C. can be formed. In this case, the resistive film 8 preferably covers the insulating region 7 that has the insulating thickness TB of not less than 2200 nm.

The resistive film 8 is especially preferably arranged inside the insulating layer 5 such as not to be positioned within the thickness range of less than 3100 nm on the basis of the first end 5a of the insulating layer 5. With this structure, the resistive film 8 having the first order coefficient TCR1 in a range of not less than −20 ppm/° C. and not more than +25 ppm/° C. can be formed. In this case, the resistive film 8 preferably covers the insulating region 7 that has the thickness of not less than 3100 nm.

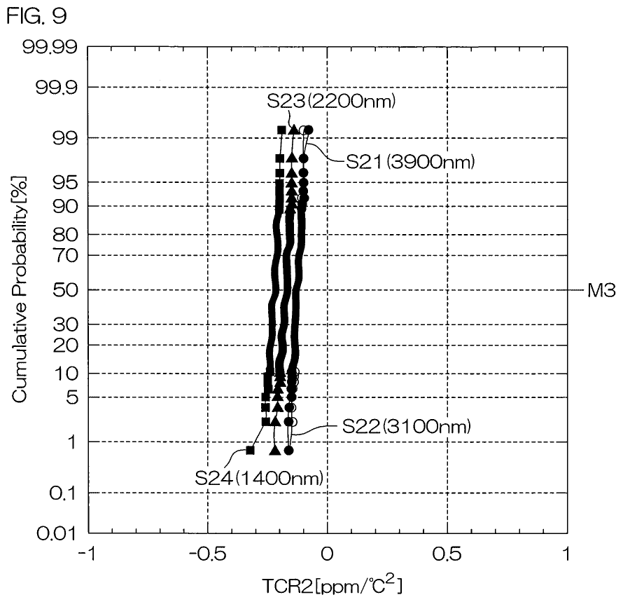

FIG. 9 is a graph showing the second order coefficients TCR2 of the TCRs of the resistive films 8. In FIG. 9, the ordinate shows a cumulative probability [%] and the abscissa shows the second order coefficient TCR2 [ppm/° C.²] of the TCR of the resistive film 8. A first characteristic S21, a second characteristic S22, a third characteristic S23, and a fourth characteristic S24 are shown in FIG. 9.

The first characteristic S21 represents a characteristic of the resistive film 8 according to the first configuration example. The second characteristic S22 represents a characteristic of the resistive film 8 according to the second configuration example. The third characteristic S23 represents a characteristic of the resistive film 8 according to the third configuration example. The fourth characteristic S24 represents a characteristic of the resistive film 8 according to the fourth configuration example. In all cases, a design value of the second order coefficient TCR2 is not less than −0.5 ppm/° C.² and not more than +0.5 ppm/° C.². An optimal value of the second order coefficient TCR2 is 0 ppm/° C.².

Referring to the first characteristic S21, with the resistive film 8 according to the first configuration example, the second order coefficient TCR2 falls within a range of not less than −0.16 ppm/° C.² and not more than −0.08 ppm/° C.² and a median value M3 (50%) is approximately −0.13 ppm/° C.². The second order coefficient TCR2 according to the first characteristic S21 falls within a range of not less than −0.15 ppm/° C.² and not more than −0.1 ppm/° C.² in a range of ±20% on a basis of the median value M3 (50%).

Referring to the second characteristic S22, with the resistive film 8 according to the second configuration example, the second order coefficient TCR2 falls within a range of not less than −0.16 ppm/° C.² and not more than −0.10 ppm/° C.² and the median value M3 (50%) is approximately −0.13 ppm/° C.². The second order coefficient TCR2 according to the second characteristic S22 falls within a range of not less than −0.15 ppm/° C.² and not more than −0.1 ppm/° C.² in a range of ±20% on the basis of the median value M3 (50%).

Referring to the third characteristic S23, with the resistive film 8 according to the third configuration example, the second order coefficient TCR2 falls within a range of not less than −0.23 ppm/° C.² and not more than −0.14 ppm/° C.² and the median value M3 (50%) is approximately −0.17 ppm/° C.². Referring to the fourth characteristic S24, with the resistive film 8 according to the fourth configuration example, the second order coefficient TCR2 falls within a range of not less than −0.32 ppm/° C.² and not more than −0.19 ppm/° C.² and the median value M3 (50%) is approximately −0.22 ppm/° C.².

The second order coefficient TCR2 is dependent on the placement of the resistive film 8 and improves with increase in the distance between the first end 5a of the insulating layer 5 and the resistive film 8. Specifically, the second order coefficient TCR2 improves in the order of: the fourth configuration example, the third configuration example, the second configuration example, and the first configuration example. Since the first characteristic S21 and the second characteristic S22 are substantially matched, the second order coefficient TCR2 has a tendency to converge toward the design value without diverging due to increase in the distance between the first end 5a and the resistive film 8.

From the above results, the resistive film 8 is preferably arranged inside the insulating layer 5 such as not to be positioned within the thickness range of less than 2200 nm on the basis of the first end 5a of the insulating layer 5. With this structure, the resistive film 8 having the second order coefficient TCR2 in a range of not less than −0.23 ppm/° C.² and not more than −0.08 ppm/° C.² can be formed. In this case, the resistive film 8 preferably covers the insulating region 7 that has the insulating thickness TB of not less than 2200 nm.

The resistive film 8 especially preferably covers the insulating region 7 that has the thickness of not less than 3100 nm. With this structure, the resistive film 8 having the second order coefficient TCR2 in a range of not less than −0.16 ppm/° C.² and not more than −0.08 ppm/° C.² can be formed. In this case, the resistive film 8 is preferably arranged inside the insulating layer 5 such as not to be positioned within the thickness range of less than 3100 nm on the basis of the first end 5a of the insulating layer 5.

From the results of FIG. 7 to FIG. 9, it can be understood that the electrical characteristics of the resistive film 8 are dependent on the distance between the first end 5a of the insulating layer 5 (semiconductor chip 2) and the resistive film 8. This is because the electrical characteristics of the resistive film 8 are substantially established in the crystallizing step performed in a forming step of the resistive film 8. That is, in the crystallizing step, the base alloy film that is to be the base of the resistive film 8 is heated at the crystallization temperature. In this process, the greater a distance between the first end 5a and the base alloy film inside the insulating layer 5, the higher a heat storage effect in a region between the first end 5a and the base alloy film.

A heat amount applied to the base alloy film is thereby increased and the crystallization of the base alloy film is promoted. Consequently, the resistive film 8 of high precision is formed. Since this result is due to the heat storage effect of the insulating layer 5, there is no need to increase the crystallization temperature inside a chamber or to extend the crystallization time of the base alloy film. Therefore, if a functional device is formed in the semiconductor chip 2, generation of unnecessary heat loads on the functional device can be avoided.

Also, by providing the insulating region 7 inside the insulating layer 5 and forming the base alloy film that directly covers the insulating region 7, the resistive film 8 can be crystallized efficiently by making use of a temperature rise of the insulating region 7. That is, the insulating region 7 becomes a heat storing region in a manufacturing process. The insulating region 7 is preferably provided on the outside region 4 side outside the device region 3. With this structure, heat interference of the insulating region 7 with respect to the functional device can be suppressed. Also, the resistive film 8 can be suppressed from interfering electrically with the functional device.

The insulating layer 5 preferably has the second thermal conductivity K2 that is less than the first thermal conductivity K1 of the semiconductor chip 2. With this structure, the heat storage effect of the region between the base alloy film and the semiconductor chip 2 (specifically, a semiconductor wafer that is to be a base of the semiconductor chip 2) can be improved inside the insulating layer 5. In other words, if the distance between the semiconductor chip 2 and the resistive film 8 decreases, temperature rises of the base alloy film and the insulating layer 5 are inhibited due to dissipation of heat via the semiconductor chip 2 and the crystallization of the base alloy film is suppressed. The distance between the first end 5a and the resistive film 8 inside the insulating layer 5 must therefore be set to not less than a predetermined distance.

The electrical characteristics of the resistive film 8 have the tendencies to converge toward the design values without diverging due to increase in the distance between the first end 5a and the resistive film 8. This is considered to be because the base alloy film approaches a crystallization limit due to the heat storage effect. Referring to the evaluation results for the first configuration example and the evaluation results for the second configuration example shown in FIG. 7 to FIG. 9, it can be understood that when the distance between the first end 5a and the base alloy film becomes at least not less than 3100 nm, the resistive film 8 having electrical characteristics of high precision can be formed with stability. It can therefore be said that the distance between the first end 5a and the resistive film 8 is preferably not less than 2200 nm and especially preferably not less than 3100 nm.

The electrical characteristics of the resistive film 8 hardly vary due to a thickness of an insulator that covers the resistive film 8 (that is, the number of layers and thickness of the interlayer insulating films 6 that are positioned in layers further upward than the resistive film 8). This is because the insulator that covers the resistive film 8 is laminated after the forming step of the resistive film 8. Therefore, once the thickness position at which the resistive film 8 (base alloy film) is to be arranged is determined, the upper limit value of the thickness TA of the insulating layer 5 becomes arbitrary.

As described above, the electronic component 1 includes the semiconductor chip 2 (chip), the insulating layer 5, and the resistive film 8. The semiconductor chip 2 has the first main surface 2a (main surface). The insulating layer 5 is laminated to a thickness exceeding 2200 nm on the first main surface 2a. The insulating layer 5 has the first end 5a on the semiconductor chip 2 side and the second end 5b on the side opposite to the semiconductor chip 2. The resistive film 8 includes the alloy crystal constituted of the metal element and the nonmetal element. The resistive film 8 is arranged inside the insulating layer 5 such as not to be positioned within the thickness range of less than 2200 nm on the basis of the first end 5a. With this structure, reliability of the resistive film 8 can be improved.

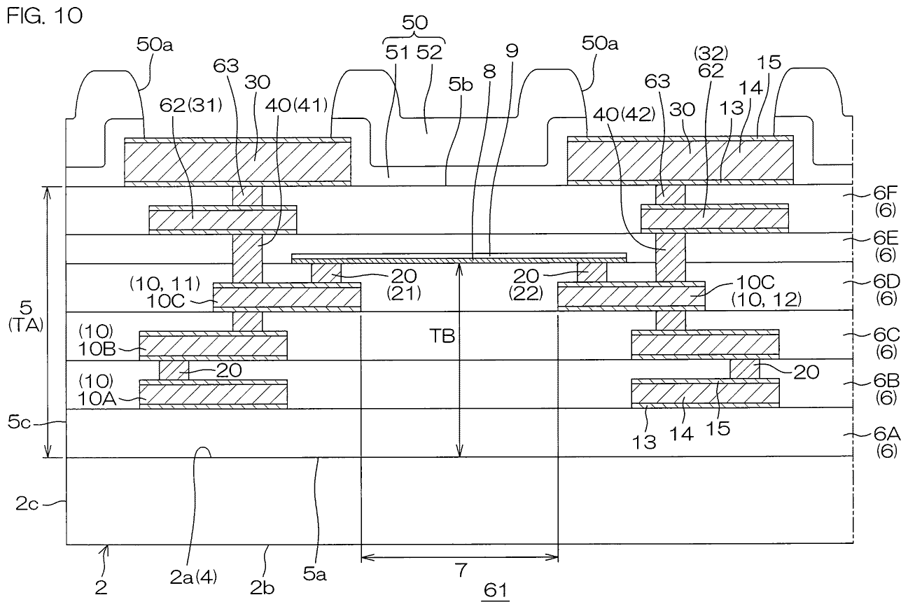

FIG. 10 corresponds to FIG. 2 and is a sectional view showing an electronic component 61 according to a second embodiment (=an embodiment with which a placement location and a connection mode of the resistive film 8 in the electronic component 1 according to the first embodiment are changed). In the following, structures corresponding to structures described for the electronic component 1 are provided with the same reference signs and description thereof shall be omitted.

Referring to FIG. 10, the electronic component 61 includes, as does the electronic component 1, the semiconductor chip 2, the device region 3, the outside region 4, the insulating layer 5, the insulating region 7, the resistive film 8, the inorganic insulating film 9, the plurality of interlayer wirings 10, the plurality of via electrodes 20, the plurality of top wirings 30, the plurality of long via electrodes 40, and the top insulating layer 50. As in the first embodiment, the insulating layer 5 includes the first to sixth interlayer insulating films 6A to 6F laminated in that order from the first main surface 2a side. In this embodiment, the insulating region 7 includes a laminated structure constituted of a portion of the first to fourth interlayer insulating films 6A to 6D and has the insulating thickness TB of not less than 2200 m. The insulating thickness TB is preferably not less than 3100 nm.

In this embodiment, the resistive film 8 is arranged inside the insulating layer 5 such as to be covered by a laminated film of not less than two layers of the interlayer insulating films 6. In this embodiment, the resistive film 8 is arranged on the fourth interlayer insulating film 6D and is covered by the fifth and sixth interlayer insulating films 6E and 6F. The resistive film 8 exclusively occupies the fourth interlayer insulating film 6D. The number of laminated layers of the interlayer insulating films 6 covering the resistive film 8 is arbitrary and may be not less than three.

In this embodiment, the plurality of interlayer wirings 10 are arranged within the thickness range between the second end 5b and the resistive film 8 inside the insulating layer 5 as well as within the thickness range between the first end 5a and the resistive film 8 inside the insulating layer 5. In this embodiment, the plurality of interlayer wirings 10 include a plurality of upper interlayer wirings 62 in addition to the first to third interlayer wirings 10A to 10C. The first to third interlayer wirings 10A to 10C are respectively laminated and arranged within the thickness range between the first end 5a and the resistive film 8 inside the insulating layer 5. Specifically, the first to third interlayer wirings 10A to 10C are respectively laminated and arranged on the first to third interlayer insulating films 6A to 6C.

The plurality of upper interlayer wirings 62 are arranged within the thickness range inside the insulating layer 5 between the second end 5b and the resistive film 8. In this embodiment, the upper interlayer wirings 62 are arranged on the fifth interlayer insulating film 6E and are covered by the sixth interlayer insulating film 6F. When not less than three layers of the interlayer insulating films 6 are laminated on the resistive film 8, the plurality of upper interlayer wirings 62 may be laminated and arranged within the thickness range between the second end 5b and the resistive film 8 inside the insulating layer 5.

The plurality of interlayer wirings 10 include the first lower wiring 11, the second lower wiring 12, the first upper wiring 31, and the second upper wiring 32 for the resistive film 8. In this embodiment, the first lower wiring 11 and the second lower wiring 12 are each constituted of one of the third interlayer wirings 10C. The first upper wiring 31 and the second upper wiring 32 are each constituted of one of the upper interlayer wirings 62. That is, in the electronic component 61, the first upper wiring 31 and the second upper wiring 32 are constituted of the interlayer wirings 10 of the top wirings 30.

The plurality of via electrodes 20 include the first via electrode 21 and the second via electrode 22 for the resistive film 8. The first via electrode 21 is interposed in a region between one end of the resistive film 8 and the first lower wiring 11 and is electrically connected to the one end of the resistive film 8 and the first lower wiring 11. The second via electrode 22 is interposed in a region between the other end of the resistive film 8 and the second lower wiring 12 and is electrically connected to the other end of the resistive film 8 and the second lower wiring 12.

In this embodiment, the plurality of long via electrodes 40 are each electrically connected to an arbitrary one of the interlayer wiring 10 and an arbitrary one of the upper interlayer wiring 62 that face each other in the thickness direction. The plurality of long via electrodes 40 include the first long via electrode 41 and the second long via electrode 42 for the resistive film 8. The first long via electrode 41 is interposed in a region between the first lower wiring 11 and the first upper wiring 31 (upper interlayer wiring 62) and is electrically connected to the first lower wiring 11 and the first upper wiring 31. The second long via electrode 42 is interposed in a region between the second lower wiring 12 and the second upper wiring 32 (upper interlayer wiring 62) and is electrically connected to the second lower wiring 12 and the second upper wiring 32.

The electronic component 61 includes a plurality of top via electrodes 63. The plurality of top via electrodes 63 are each electrically connected to an arbitrary one of the interlayer wiring 10 (upper interlayer wiring 62) and an arbitrary one of the top wiring 30 that face each other in the thickness direction. As with the plurality of via electrodes 20, the plurality of top via electrodes 63 each have the laminated structure that includes the via barrier film 24 and the via main body 25 that are laminated in that order from the inner wall of the via hole 23 formed in the corresponding interlayer insulating film 6.

As described above, even with the electronic component 61, the same effects as the effects described for the electronic component 1 are exhibited.

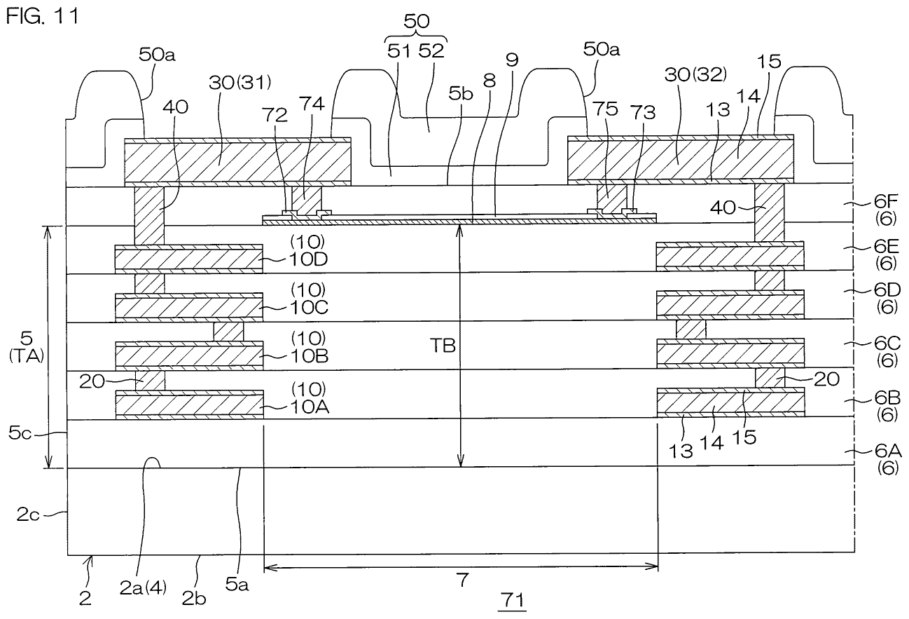

FIG. 11 corresponds to FIG. 2 and is a sectional view showing an electronic component 71 according to a third embodiment (=an embodiment with which the connection mode of the resistive film 8 in the electronic component 1 according to the first embodiment is changed). In the following, structures corresponding to structures described for the electronic component 1 are provided with the same reference signs and description thereof shall be omitted.

Referring to FIG. 11, the electronic component 71 includes, as does the electronic component 1, the semiconductor chip 2, the device region 3, the outside region 4, the insulating layer 5, the insulating region 7, the resistive film 8, the inorganic insulating film 9, the plurality of interlayer wirings 10, the plurality of via electrodes 20, the plurality of top wirings 30, the plurality of long via electrodes 40, and the top insulating layer 50. As in the first embodiment, the insulating layer 5 includes the first to sixth interlayer insulating films 6A to 6F laminated in that order from the first main surface 2a side. In this embodiment, the insulating region 7 includes a laminated structure constituted of a portion of the first to fifth interlayer insulating films 6A to 6E and has the insulating thickness TB of not less than 2200 m. The insulating thickness TB is preferably not less than 3100 nm.

As in the first embodiment, the resistive film 8 is arranged on the fifth interlayer insulating film 6E and is covered by the sixth interlayer insulating film 6F. The resistive film 8 is arranged in a region inside the insulating layer 5 between the second end 5b and the insulating region 7 and directly covers the insulating region 7. In this embodiment, the resistive film 8 faces the semiconductor chip 2 (first main surface 2a) across only the insulating region 7 inside the insulating layer 5. That is, the resistive film 8 does not face a conductor film (metal film) in a region between itself and the first end 5a.

As in the first embodiment, the plurality of interlayer wirings 10 are laminated and arranged within the thickness range between the first end 5a and the resistive film 8 inside the insulating layer 5 but are not arranged within the thickness range between the second end 5b and the resistive film 8 inside the insulating layer 5. The plurality of interlayer wirings 10 include the first to fourth interlayer wirings 10A to 10D. In this embodiment, the plurality of interlayer wirings 10 do not have the first lower wiring 11 and the second lower wiring 12 for the resistive film 8. As in the first embodiment, the plurality of via electrodes 20 are each electrically connected to two arbitrary interlayer wirings 10 that face each other in the thickness direction.

The plurality of top wirings 30 include the first upper wiring 31 and the second upper wiring 32 for the resistive film 8. The first upper wiring 31 faces one end portion of the resistive film 8 across a portion of the insulating layer 5 and the second upper wiring 32 faces another end portion of the resistive film 8 across a portion of the insulating layer 5. That is, the resistive film 8 is arranged inside the insulating layer 5 such as to cover the insulating region 7 and overlap with the first upper wiring 31 and the second upper wiring 32 in plan view. As in the first embodiment, the plurality of long via electrodes 40 are each electrically connected to an arbitrary one of the interlayer wiring 10 and an arbitrary one of the top wiring 30 that face each other in the thickness direction.

The electronic component 71 includes a first pad electrode 72 and a second pad electrode 73 that are arranged inside the insulating layer 5. The first pad electrode 72 penetrates through the inorganic insulating film 9 and is electrically connected to the one end portion of the resistive film 8 inside the insulating layer 5 (in this embodiment, inside the sixth interlayer insulating film 6F). The second pad electrode 73 penetrates through the inorganic insulating film 9 and is electrically connected to the other end portion of the resistive film 8 inside the insulating layer 5 (in this embodiment, inside the sixth interlayer insulating film 6F).

The electronic component 71 includes a first pad via electrode 74 and a second pad via electrode 75 that are arranged inside the insulating layer 5. The first pad via electrode 74 is interposed in a region between the first pad electrode 72 and the first upper wiring 31 and is electrically connected to the first pad electrode 72 and the first upper wiring 31. The second pad via electrode 75 is interposed in a region between the second pad electrode 73 and the second upper wiring 32 and is electrically connected to the second pad electrode 73 and the second upper wiring 32. As with the plurality of via electrodes 20, the first pad via electrode 74 and the second pad via electrode 75 each have the laminated structure that includes the via barrier film 24 and the via main body 25 that are laminated in that order from the inner wall of the via hole 23 formed in the corresponding interlayer insulating film 6.

As described above, even with the electronic component 71, the same effects as the effects described for the electronic component 1 are exhibited. With the present embodiment, an example where the resistive film 8 faces the semiconductor chip 2 across only the insulating region 7 in the thickness direction of the insulating layer 5 was described. However, a portion of the interlayer insulating wirings 10 may be interposed in a region between the first end 5a and the resistive film 8. That is, the resistive film 8 may face the insulating region 7 and a portion of a conductor film (metal film) in the thickness direction of the insulating layer 5.

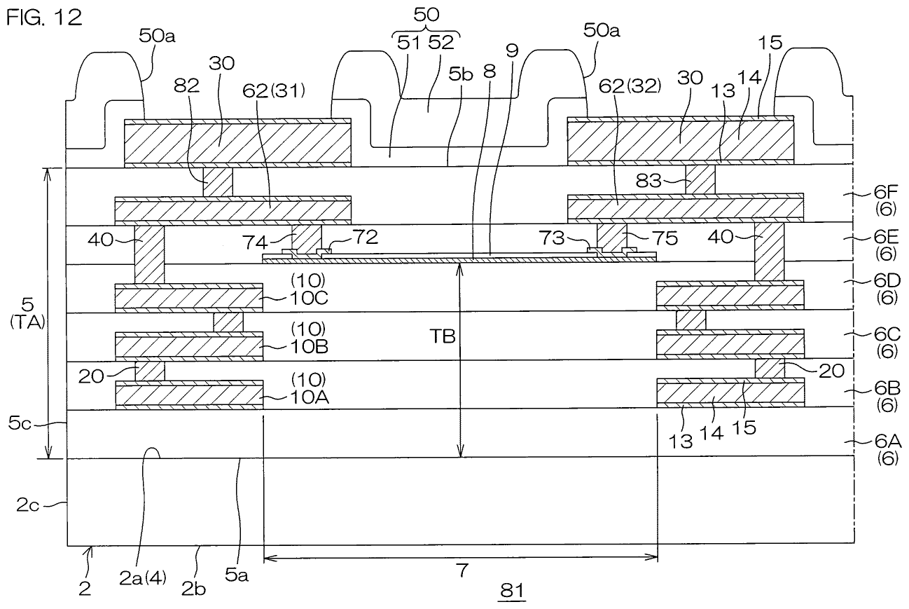

FIG. 12 corresponds to FIG. 2 and is a sectional view showing an electronic component 81 according to a fourth embodiment (=an embodiment with which the placement location and the connection mode of the resistive film 8 in the electronic component 71 according to the third embodiment are changed). In the following, structures corresponding to structures described for the electronic component 71 are provided with the same reference signs and description thereof shall be omitted.

Referring to FIG. 12, the electronic component 81 includes, as does the electronic component 71, the semiconductor chip 2, the device region 3, the outside region 4, the insulating layer 5, the insulating region 7, the resistive film 8, the inorganic insulating film 9, the plurality of interlayer wirings 10, the plurality of via electrodes 20, the plurality of top wirings 30, the plurality of long via electrodes 40, the top insulating layer 50, the first pad electrode 72, the second pad electrode 73, the first pad via electrode 74, and the second pad via electrode 75. As in the electronic component 71, the insulating layer 5 includes the first to sixth interlayer insulating films 6A to 6F laminated in that order from the first main surface 2a side. In this embodiment, the insulating region 7 includes a laminated structure constituted of a portion of the first to fourth interlayer insulating films 6A to 6D and has the insulating thickness TB of not less than 2200 m. The insulating thickness TB is preferably not less than 3100 nm.

In this embodiment, the resistive film 8 is arranged inside the insulating layer 5 such as to be covered by a laminated film of not less than two layers of the interlayer insulating films 6. In this embodiment, the resistive film 8 is arranged on the fourth interlayer insulating film 6D and is covered by the fifth and sixth interlayer insulating films 6E and 6F. The resistive film 8 exclusively occupies the fourth interlayer insulating film 6D. The number of laminated layers of the interlayer insulating films 6 covering the resistive film 8 is arbitrary and may be not less than three.

In this embodiment, the plurality of interlayer wirings 10 are arranged within the thickness range between the second end 5b and the resistive film 8 inside the insulating layer 5 as well as within the thickness range between the first end 5a and the resistive film 8 inside the insulating layer 5. In this embodiment, the plurality of interlayer wirings 10 include the upper interlayer wirings 62 in addition to the first to third interlayer wirings 10A to 10C. The first to third interlayer wirings 10A to 10C are respectively laminated and arranged within the thickness range between the first end 5a and the resistive film 8 inside the insulating layer 5. Specifically, the first to third interlayer wirings 10A to 10C are respectively laminated and arranged laminated on the first to third interlayer insulating films 6A to 6C.

The plurality of upper interlayer wirings 62 are arranged within the thickness range between the second end 5b and the resistive film 8 inside the insulating layer 5. In this embodiment, the upper interlayer wirings 62 are arranged on the fifth interlayer insulating film 6E and are covered by the sixth interlayer insulating film 6F. When not less than three layers of the interlayer insulating films 6 are laminated on the resistive film 8, the plurality of upper interlayer wirings 62 may be laminated and arranged within the thickness range between the second end 5b and the resistive film 8 inside the insulating layer 5.

The plurality of interlayer wirings 10 include the first upper wiring 31 and the second upper wiring 32 for the resistive film 8. In this embodiment, the first upper wiring 31 and the second upper wiring 32 are each constituted of one of the upper interlayer wirings 62. In this embodiment, the plurality of long via electrodes 40 are each electrically connected to an arbitrary one of the interlayer wiring 10 and an arbitrary one of the upper interlayer wiring 62 that face each other in the thickness direction. The plurality of long via electrodes 40 include the first long via electrode 41 and the second long via electrode 42. The first long via electrode 41 is interposed between an arbitrary one of the interlayer wiring 10 and the first upper wiring 31 (upper interlayer wiring 62) and is electrically connected to the arbitrary interlayer wiring 10 and the first upper wiring 31. The second long via electrode 42 is interposed between an arbitrary one of the interlayer wiring 10 and the second upper wiring 32 (upper interlayer wiring 62) and is electrically connected to the arbitrary interlayer wiring 10 and the second upper wiring 32.

The first pad electrode 72 penetrates through the inorganic insulating film 9 and is electrically connected to one end portion of the resistive film 8 inside the insulating layer 5 (in this embodiment, inside the fifth interlayer insulating film 6E). The second pad electrode 73 penetrates through the inorganic insulating film 9 and is electrically connected to another end portion of the resistive film 8 inside the insulating layer 5 (in this embodiment, inside the fifth interlayer insulating film 6E). The first pad via electrode 74 is interposed in a region between the first pad electrode 72 and the first upper wiring 31 (upper interlayer wiring 62) and is electrically connected to the first pad electrode 72 and the first upper wiring 31. The second pad via electrode 75 is interposed in a region between the second pad electrode 73 and the second upper wiring 32 (upper interlayer wiring 62) and is electrically connected to the second pad electrode 73 and the second upper wiring 32.

The electronic component 81 includes a first top via electrode 82 and a second top via electrode 83 that are arranged inside the insulating layer 5. The first top via electrode 82 is interposed between the first upper wiring 31 (upper interlayer wiring 62) and an arbitrary one of the top wiring 30 and is electrically connected to the first upper wiring 31 and the arbitrary top wiring 30. The second top via electrode 83 is interposed between the second upper wiring 32 (upper interlayer wiring 62) and an arbitrary one of the top wiring 30 and is electrically connected to the second upper wiring 32 and the arbitrary top wiring 30. As with the plurality of via electrodes 20, the first top via electrode 82 and the second top via electrode 83 each have the laminated structure that includes the via barrier film 24 and the via main body 25 that are laminated in that order from the inner wall of the via hole 23 formed in the corresponding interlayer insulating film 6.

As described above, even with the electronic component 81, the same effects as the effects described for the electronic component 1 are exhibited.

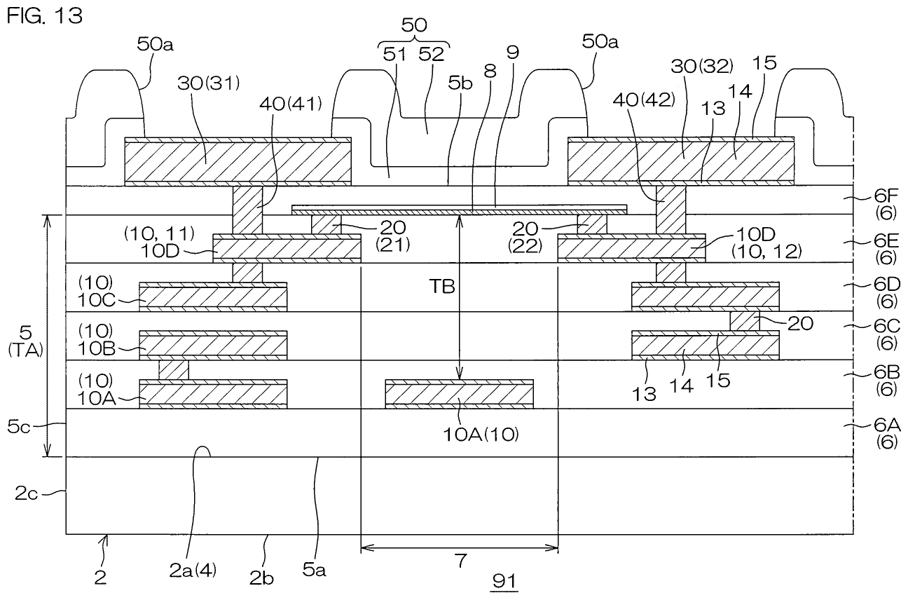

FIG. 13 corresponds to FIG. 2 and is a sectional view showing an electronic component 91 according to a fifth embodiment (=an embodiment with which a form of the insulating region 7 in the electronic component 1 according to the first embodiment is changed). In the following, structures corresponding to structures described for the electronic component 1 are provided with the same reference signs and description thereof shall be omitted.

With the electronic component 1, an example where the insulating region 7 has the insulating thickness TB with the first end 5a as the basis (zero point) was described. On the other hand, with reference to FIG. 13, with the electronic component 91, the insulating region 7 has the insulating thickness TB with an arbitrary one of the interlayer wiring 10 arranged on the first end 5a side inside the insulating layer 5 as the basis (zero point). In FIG. 13, the insulating region 7 has, as an example, the insulating thickness TB with the first interlayer wiring 10A as the basis (zero point). Even in this case, the insulating thickness TB is preferably not less than 2200 μm. The insulating thickness TB is especially preferably not less than 3100 nm.

As described above, even with the electronic component 91, the same effects as the effects described for the electronic component 1 are exhibited. The insulating region 7 according to the fifth embodiment can also be applied to the second to fourth embodiments in addition to the first embodiment.

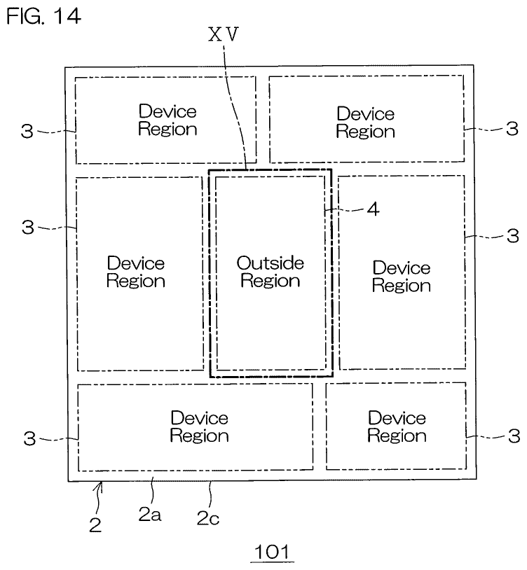

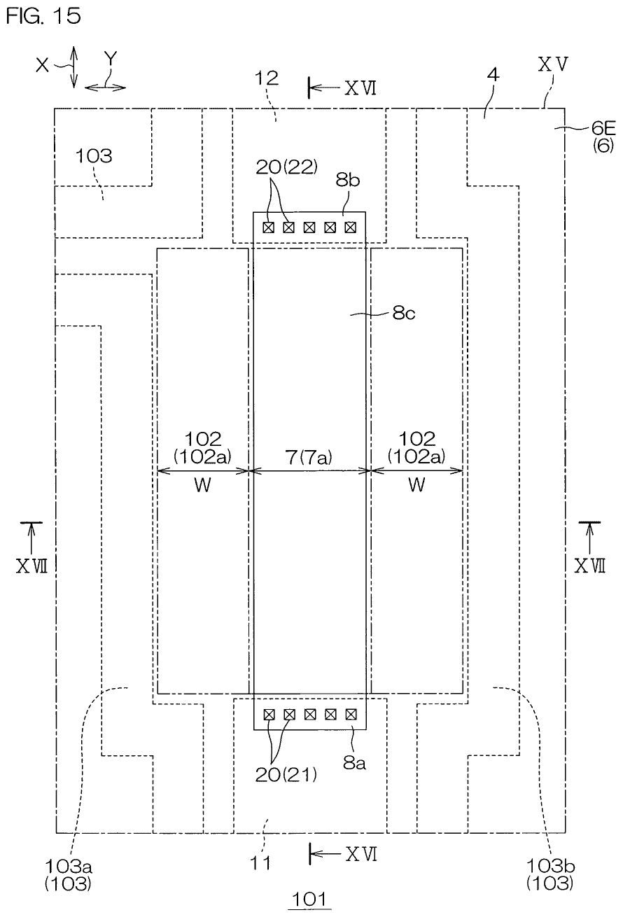

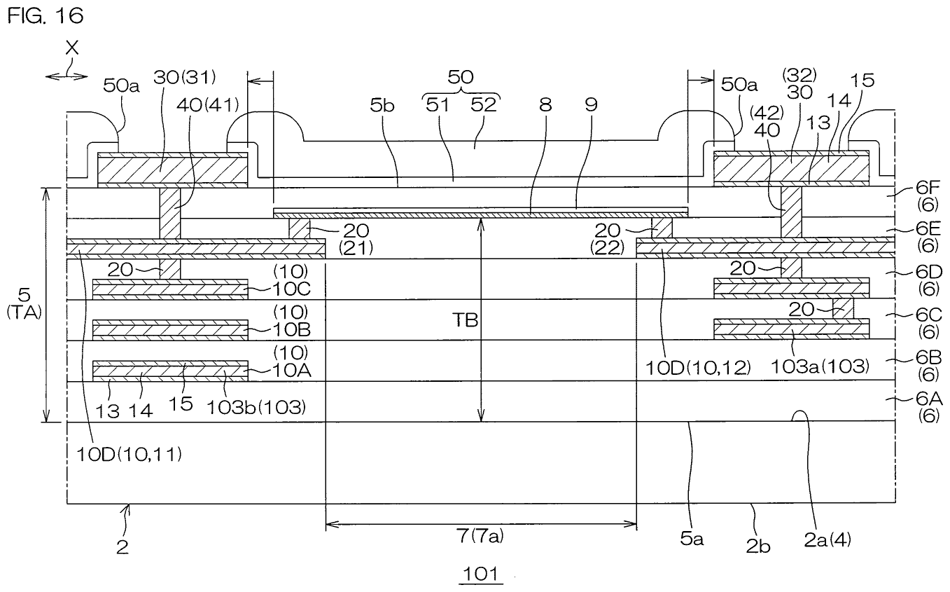

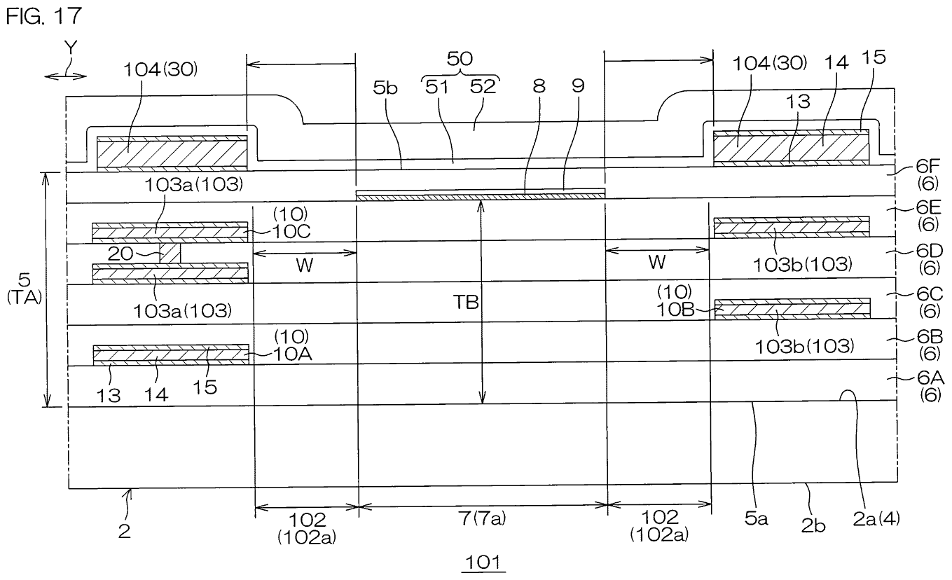

FIG. 14 is a schematic plan view showing an electronic component 101 according to a sixth embodiment. FIG. 15 is an enlarged view showing a region XV shown in FIG. 14 together with the resistive film 8 according to a first pattern. FIG. 16 is a sectional view taken along line XVI-XVI shown in FIG. 15. FIG. 17 is a sectional view taken along line XVII-XVII shown in FIG. 15. In the following, structures corresponding to structures shown in FIG. 1 to FIG. 13 are provided with the same reference signs and while a portion of the structures shall be described in detail using viewpoints and definitions different from the first embodiment, etc., description of other structures shall be omitted or simplified.

As in the first embodiment, the electronic component 101 includes the semiconductor chip 2, the device regions 3, and the outside region 4. In this embodiment, the electronic component 101 includes a plurality of the device regions 3 and at least one outside region 4 that are provided in the first main surface 2a. The plurality of device regions 3 are each demarcated in an inner portion of the first main surface 2a at intervals from the side surface 2c in plan view.

The number, placements, and shapes of the device regions 3 are arbitrary and not restricted to a specific number, placements, and shapes. As a matter of course, the electronic component 101 may have a single device region 3 as in the first embodiment. The at least one outside region 4 is provided in a region of the first main surface 2a between at least two device regions 3. In this embodiment, the at least one outside region 4 is provided in a region demarcated from four directions by four device regions 3 in an inner portion of the first main surface 2a.

As in the first embodiment, the electronic component 101 includes the insulating layer 5 that is laminated on the first main surface 2a. The insulating layer 5 includes a plurality of the interlayer insulating films 6 (in this embodiment, the first to sixth interlayer insulating films 6A to 6F) and has the thickness TA (2200 nm<TA) described above. In this embodiment, the insulating layer 5 covers the plurality of device regions 3 and the outside region 4. In this embodiment, the plurality of interlayer insulating films 6 each have a flat outer surface. The outer surface of each interlayer insulating film 6 is flattened by a CMP (chemical mechanical polishing) method.

As in the first embodiment, the electronic component 101 includes the resistive film 8, the inorganic insulating film 9, the plurality of interlayer wirings 10 (first to fourth interlayer wirings 10A to 10D), the first lower wiring 11, the second lower wiring 12, and the insulating region 7. As in the first embodiment, the plurality of interlayer wirings 10 each have the laminated structure that includes the first barrier film 13, the main body film 14, and the second barrier film 15.

As in the first embodiment, the resistive film 8 is arranged inside the insulating layer 5. The resistive film 8 is arranged at a portion that covers the outside region 4 inside the insulating layer 5. That is, in this embodiment, the resistive film 8 is provided in a region between at least two device regions 3 in plan view. Specifically, the resistive film 8 is provided in a region demarcated from four directions by four device regions 3 in plan view. The resistive film 8 has a first end portion 8a on one side, a second end portion 8b on another side, and a main resistive body portion 8c between the first end portion 8a and the second end portion 8b. In the following, a direction in which a rectilinear line joining the first end portion 8a and the second end portion 8b extends shall be referred to as a first direction X and an intersecting direction (specifically, an orthogonal direction) with respect to the first direction X shall be referred to as a second direction Y.

The first end portion 8a and the second end portion 8b are electrical end connections and are portions that face other members in thickness direction of the insulating layer 5. The main resistive body portion 8c is a portion that is positioned outside the first end portion 8a and the second end portion 8b and connects the first end portion 8a and the second end portion 8b. The main resistive body portion 8c extends as a band between the first end portion 8a and the second end portion 8b. In this embodiment, the main resistive body portion 8c extends as a rectilinear band (a rectangular shape) along the first direction X. A width of the main resistive body portion 8c may be not less than 1 μm and not more than 200 μm. The width of the main resistive body portion 8c is a width in the direction (second direction Y) orthogonal to the direction (first direction X) in which the main resistive body portion 8c extends.

The first lower wiring 11 is arranged between the first main surface 2a and the first end portion 8a of the resistive film 8 inside the insulating layer 5. In this embodiment, the first lower wiring 11 is constituted of one of the fourth interlayer wirings 10D. The first lower wiring 11 is led out in a direction opposite to the second end portion 8b of the resistive film 8 from a region below the first end portion 8a of the resistive film 8 to a region outside the resistive film 8 in plan view. The first lower wiring 11 has one end portion positioned below the first end portion 8a of the resistive film 8 and another end portion positioned in the region outside the resistive film 8. In this embodiment, the first lower wiring 11 (one end portion) is formed to be wider than the main resistive body portion 8c of the resistive film 8 in the second direction Y.

The second lower wiring 12 is arranged between the first main surface 2a and the second end portion 8b of the resistive film 8 at an interval, in the first direction X, from the first lower wiring 11. In this embodiment, the second lower wiring 12 is constituted of one of the fourth interlayer wirings 10D. The second lower wiring 12 is led out in a direction opposite to the first end portion 8a of the resistive film 8 from a region below the second end portion 8b of the resistive film 8 to the region outside the resistive film 8 in plan view. The second lower wiring 12 faces the first lower wiring 11 across a portion of the insulating layer 5. The second lower wiring 12 has one end portion positioned below the second end portion 8b of the resistive film 8 and another end portion positioned in the region outside the resistive film 8. In this embodiment, the second lower wiring 12 (one end portion) is formed to be wider than the resistive film 8 (main resistive body portion 8c) in the second direction Y.

As in the first embodiment, the insulating region 7 is demarcated in a region between the first lower wiring 11 and the second lower wiring 12 inside the insulating layer 5. The insulating region 7 has the above-described insulating thickness TB (=not less than 2200 nm; TB<TA) in regard to the thickness direction of the insulating layer 5. The insulating region 7 is formed of only an insulator portion 7a that is positioned in a thickness range between the first main surface 2a and the resistive film 8 in the insulating layer 5. The insulator portion 7a is a portion that does not have a conductor film (metal film) and has only an insulator in the thickness direction of the insulating layer 5. The insulator portion 7a has a laminated structure that is constituted of a portion of the plurality of interlayer insulating films 6 (in this embodiment, the first to fifth interlayer insulating films 6A to 6E) positioned in the thickness range between the first main surface 2a and the resistive film 8.

The insulating region 7 (insulator portion 7a) is formed across an entire area of a facing region between the first lower wiring 11 and the second lower wiring 12 inside the insulating layer 5 in plan view and sectional view. Also, the insulating region 7 is formed across an entire area of a portion in which an entire area of the main resistive body portion 8c overlaps with the first main surface 2a in plan view and sectional view. In this embodiment, the insulator portion 7a is formed in a quadrilateral shape that includes an entirety of the main resistive body portion 8c on a basis of portions of a peripheral edge of the main resistive body portion 8c that are positioned outermost in the second direction Y in plan view.

The electronic component 101 includes forbidden regions 102 that expand the insulating region 7 to ranges outside the resistive film 8. The forbidden regions 102 are regions in which placement of a conductor film (metal film, etc.) inside the insulating layer 5 is forbidden. The forbidden regions 102 may also be referred to as an “insulation expansion regions.” The forbidden regions 102 each include an insulation expansion portion 102a with which the insulator portion 7a of the insulating region 7 is expanded from a peripheral edge of the resistive film 8 to the range outside the resistive film 8. Specifically, the insulation expansion portions 102a expand the insulator portion 7a in a direction (second direction Y) orthogonal to a facing direction (first direction X) of the first lower wiring 11 and the second lower wiring 12 from a region between the first lower wiring 11 and the second lower wiring 12 in plan view.

In this embodiment, the forbidden regions 102 expand the insulating region 7 in quadrilateral shapes in plan view. The insulation expansion portions 102a cover the outside region 4. The insulation expansion portions 102a preferably cover the outside region 4 at intervals from the plurality of device regions 3. As a matter of course, the insulation expansion portions 102a may each traverse the outside region 4 and cover at least one device region 3.

As with the insulating region 7, the forbidden regions 102 form heat storing regions for the resistive film 8. As with the insulating thickness TB of the insulating region 7, an expansion width W of each forbidden region 102 is preferably not less than 2200 nm (2200 nm≤W, TB). The expansion width W is a width along the second direction Y of each forbidden region 102 with the peripheral edge of the resistive film 8 as a basis (zero point) in plan view. In this case, the forbidden regions 102 exhibit the same actions and effects as the actions and effects of the insulating region 7 in regard to a lateral direction along the second end 5b of the insulating layer 5. If the insulating thickness TB of the insulating region 7 is not less than 3100 nm, the expansion width W may be not less than 3100 nm (3100 nm≤W, TB).

The expansion width W may be not less than the insulating thickness TB of the insulating region 7 (TB≤W) or may be less than the insulating thickness TB (TB>W). The expansion width W may be not less than the thickness TA of the insulating layer 5 (TA≤W) or may be less than the thickness TA (TA>W). An upper limit value of the expansion width W is arbitrary. The upper limit value of the expansion width W is preferably not more than 10 times the insulating thickness TB (W≤10×TB) in view of a size of the semiconductor chip 2, a layout of the plurality of interlayer wirings 10, etc. The expansion width W is especially preferably not less than 3.5 μm and not more than 20 μm. That is, each forbidden region 102 (insulation expansion portion 102a) preferably expands the insulating region 7 (insulator portion 7a) within a range of not less than 3.5 μm and not more than 20 μm from the peripheral edge of the resistive film 8 in plan view.

The electronic component 101 includes a plurality of third wirings 103 that are arranged inside the insulating layer 5. The plurality of third wirings 103 are each constituted of an interlayer wiring 10 other than the first lower wiring 11 and the second lower wiring 12. The plurality of third wirings 103 are arranged at layers (first to fourth interlayer insulating films 6A to 6D) other than the layer (fifth interlayer insulating film 6E) at which the resistive film 8 is arranged. The plurality of third wirings 103 are arranged away from the resistive film 8, the first lower wiring 11, and the second lower wiring 12 inside the insulating layer 5.

The plurality of third wirings 103 are arranged in the region outside the resistive film 8 inside the insulating layer 5 at intervals from the peripheral edge of the resistive film 8 such as not to overlap with the resistive film 8 in plan view. Specifically, the plurality of third wirings 103 are arranged in a region outside the insulating region 7 and the forbidden regions 102 in plan view and do not face the resistive film 8, the insulating region 7, and the forbidden regions 102 across a portion of the insulating layer 5.

At least one third wiring 103 among the plurality of third wirings 103 is arranged away from the first lower wiring 11 and the second lower wiring 12 in the same layer as the first lower wiring 11 and the second lower wiring 12. At least one third wiring 103 among the plurality of third wirings 103 is arranged on a layer (among the first to third interlayer insulating films 6A to 6C) different from the layer (fourth interlayer insulating film 6D) on which the first lower wiring 11 and the second lower wiring 12 are arranged. At least one third wiring 103 may face either or both of the first lower wiring 11 and the second lower wiring 12 in the thickness direction of the insulating layer 5 from a layer different from the first lower wiring 11 and the second lower wiring 12.

The plurality of third wirings 103 include at least one (a plurality in this embodiment) of connection wirings 103a that are electrically connected to either or both of the semiconductor chip 2 (specifically, the functional device) and the resistive film 8. The plurality of third wirings 103 include at least one (a plurality in this embodiment) of dummy wirings 103b that are electrically separated from the semiconductor chip 2 (specifically, the functional device) and the resistive film 8. Specifically, the dummy wirings 103b are formed to be in an electrically floating state.

The plurality of dummy wirings 103b protect the plurality of interlayer wirings 10 from undesirable corrosion in an etching step performed on the plurality of interlayer wirings 10. The plurality of dummy wirings 103b protect the interlayer insulating films 6 from undesirable undulation in a forming step of the interlayer insulating films 6. The interlayer insulating films 6 that are suppressed in undulation are flattened appropriately by the CMP method.

In this embodiment, the plurality of connection wirings 103a and the plurality of dummy wirings 103b are respectively formed on the first to fourth interlayer insulating films 6A to 6D. In the same layer as the first lower wiring 11 and the second lower wiring 12, the plurality of connection wirings 103a and the plurality of dummy wirings 103b are arranged at intervals, in lateral directions along the second end 5b of the insulating layer 5, from the first lower wiring 11 and the second lower wiring 12. An example where the connection wiring 103a is arranged on one side (left side of the sheet) and the dummy wiring 103b is arranged on another side (right side of the sheet) in the same layer as the first lower wiring 11 and the second lower wiring 12 is shown in FIG. 15 and FIG. 16.

The plurality of dummy wirings 103b are respectively arranged on the first to fourth interlayer insulating films 6A to 6D such that, in plan view, a proportion at which a total planar area of the plurality of interlayer wirings 10 (electrode films) occupies an outer surface of each interlayer insulating film 6 that is a film forming object is not less than 20% and not more than 80%. The proportion of the total planar area is preferably not less than 25% and not more than 65%. At least one third wiring 103 (interlayer wiring 10) is arranged in the region outside the insulating region 7 and the forbidden regions 102 within a range of not less than 1.5 times and not more than 4 times a width of the resistive film 8 on a basis of the peripheral edge of the resistive film 8.

The plurality of third wirings 103 are preferably arranged not less than 2200 nm away from the peripheral edge of the resistive film 8 in accordance with the expansion width W of the forbidden regions 102 in plan view. The plurality of third wirings 103 are preferably arranged not less than 3100 nm away from the peripheral edge of the resistive film 8. The plurality of third wirings 103 are especially preferably arranged not less than 3.5 μm away from the peripheral edge of the resistive film 8. The plurality of third wirings 103 are preferably not arranged at an interval of not less than 20 μm from the peripheral edge of the resistive film 8 in plan view. That is, the plurality of third wirings 103 are especially preferably arranged within a range of not less than 3.5 μm and within 20 μm from the peripheral edge of the resistive film 8 in plan view.

As in the first embodiment, the electronic component 101 includes the plurality of via electrodes 20 (first via electrodes 21 and second via electrodes 22), the plurality of top wirings 30 (first upper wiring 31 and second upper wiring 32), the plurality of long via electrodes 40 (first long via electrode 41 and second long via electrode 42), and the top insulating layer 50.

As in the first embodiment, the plurality of via electrodes 20 each have the laminated structure including the via barrier film 24 and the via main body 25 that are laminated in that order from the inner wall of the via hole 23 formed in the corresponding interlayer insulating film 6. As in the first embodiment, the plurality of via electrodes 20 are each electrically connected to two arbitrary interlayer wirings 10 that face each other in the thickness direction and include the first via electrode 21 and the second via electrode 22 for the resistive film 8.

As in the first embodiment, the first via electrode 21 is interposed between the first end portion 8a of the resistive film 8 and one end portion of the first lower wiring 11 and is electrically connected to the first end portion 8a of the resistive film 8 and the one end portion of the first lower wiring 11. In this embodiment, a plurality of the first via electrodes 21 are interposed between the first end portion 8a of the resistive film 8 and the one end portion of the first lower wiring 11. In this embodiment, the plurality of first via electrodes 21 are aligned in a single column at intervals in the second direction Y in plan view.

The plurality of first via electrodes 21 may be aligned in a matrix or a staggered arrangement at intervals in the first direction X and the second direction Y in plan view. Each first via electrode 21 may be formed in a circular shape or a polygonal shape (for example, a quadrilateral shape) in plan view. The number of the first via electrodes 21 is arbitrary and the single first via electrode 21 may be arranged.

As in the first embodiment, the second via electrode 22 is interposed between the second end portion 8b of the resistive film 8 and one end portion of the second lower wiring 12 and is electrically connected to the second end portion 8b of the resistive film 8 and the one end portion of the second lower wiring 12. In this embodiment, a plurality of the second via electrodes 22 are interposed between the second end portion 8b of the resistive film 8 and the one end portion of the second lower wiring 12. In this embodiment, the plurality of second via electrodes 22 are aligned in a single column at intervals in the second direction Y in plan view. The plurality of second via electrodes 22 face the plurality of first via electrodes 21 across the insulating region 7 in the first direction X in plan view.

The plurality of second via electrodes 22 may be aligned in a matrix or a staggered arrangement at intervals in the first direction X and the second direction Y in plan view. Each second via electrode 22 may be formed in a circular shape or a polygonal shape (for example, a quadrilateral shape) in plan view. The number of the second via electrodes 22 is arbitrary and the single second via electrode 22 may be arranged.

As in the first embodiment, the plurality of top wirings 30 each have the laminated structure including the first barrier film 13, the main body film 14, and the second barrier film 15 that are laminated in that order from the semiconductor chip 2 side (insulating layer 5 side). In this embodiment, the plurality of top wirings 30 are arranged, on the second end 5b of the insulating layer 5, at intervals, in the region outside the resistive film 8, from the peripheral edge of the resistive film 8 such as not to overlap with the resistive film 8 in plan view. Specifically, the plurality of top wirings 30 are arranged in the region outside the insulating region 7 and the forbidden regions 102 in plan view and do not face the resistive film 8, the insulating region 7, and the forbidden regions 102 across a portion of the insulating layer 5. The plurality of top wirings 30 each face an arbitrary one of the interlayer wiring 10 in the thickness direction of the insulating layer 5.

As in the first embodiment, the plurality of top wirings 30 include the first upper wiring 31 and the second upper wiring 32 for the resistive film 8. The first upper wiring 31 is arranged in the region outside the insulating region 7 and the forbidden regions 102 in plan view and faces the first lower wiring 11 at a lower layer across a portion of the insulating layer 5. The first upper wiring 31 does not face the resistive film 8 in plan view and sectional view. The second upper wiring 32 is arranged in the region outside the insulating region 7 and the forbidden regions 102 in plan view and faces the second lower wiring 12 at a lower layer across a portion of the insulating layer 5. The second upper wiring 32 does not face the resistive film 8 in plan view and sectional view.

In this embodiment, the plurality of top wirings 30 include at least one (a plurality in this embodiment) of dummy top wirings 104 that are electrically separated from the semiconductor chip 2 (specifically, the functional device) and the resistive film 8. An example where a plurality of the dummy top wirings 104 are arranged is shown in FIG. 17. Specifically, the dummy top wirings 104 are formed to be in an electrically floating state. The plurality of dummy top wirings 104 protect the plurality of top wirings 30 from undesirable corrosion in an etching step performed on the plurality of top wirings 30.

The plurality of dummy top wirings 104 are respectively arranged on the uppermost interlayer insulating film 6 (in this embodiment, the sixth interlayer insulating film 6F) such that, in plan view, a proportion at which a total planar area of the plurality of top wirings 30 (electrode films) occupies an outer surface of the uppermost interlayer insulating film 6 that is a film forming object is not less than 20% and 80%. The proportion of the total planar area is preferably not less than 25% and not more than 65%.

The plurality of top wirings 30 are preferably arranged not less than 2200 nm away from the peripheral edge of the resistive film 8 in accordance with the expansion width W of the forbidden regions 102 in plan view. The plurality of top wirings 30 are preferably arranged not less than 3100 nm away from the peripheral edge of the resistive film 8. The plurality of top wirings 30 are especially preferably arranged not less than 3.5 μm away from the peripheral edge of the resistive film 8. The plurality of top wirings 30 are preferably not arranged at an interval of not less than 20 μm from the peripheral edge of the resistive film 8 in plan view. That is, the plurality of top wirings 30 are especially preferably arranged within a range of not less than 3.5 μm and within 20 μm from the peripheral edge of the resistive film 8 in plan view.

As in the first embodiment, the plurality of long via electrodes 40 each have the laminated structure including the via barrier film 24 and the via main body 25 that are laminated in that order from the inner wall of the via hole 23 formed in the corresponding interlayer insulating film 6. As in the first embodiment, the plurality of long via electrodes 40 are each electrically connected to an arbitrary one of the interlayer wiring 10 and an arbitrary one of the top wiring 30 that face each other in the thickness direction and include the first long via electrode 41 and the second long via electrode 42 for the resistive film 8.

As in the first embodiment, the first long via electrode 41 is interposed in a region between the first lower wiring 11 and the first upper wiring 31 and is electrically connected to the first lower wiring 11 and the first upper wiring 31. As in the first embodiment, the second long via electrode 42 is interposed in a region between the second lower wiring 12 and the second upper wiring 32 and is electrically connected to the second lower wiring 12 and the second upper wiring 32.

The first lower wiring 11 may be electrically connected to an interlayer wiring 10 (third wiring 103) at a lower layer via a via electrode 20. In this case, the first upper wiring 31 does not necessarily have to be electrically connected to the first lower wiring 11 and may be electrically connected via the first long via electrode 41 to an arbitrary one of the interlayer wiring 10 (third wiring 103) positioned at a lower layer. The second lower wiring 12 may be electrically connected to an interlayer wiring 10 (third wiring 103) at a lower layer via a via electrode 20. In this case, the second upper wiring 32 does not necessarily have to be electrically connected to the second lower wiring 12 and may be electrically connected via the second long via electrode 42 to an arbitrary one of the interlayer wiring 10 (third wiring 103) positioned at a lower layer.

As in the first embodiment, the electronic component 101 includes the top insulating layer 50 that partially covers the plurality of top wirings 30 on the second end 5b of the insulating layer 5. As in the first embodiment, the top insulating layer 50 has the laminated structure that includes the first insulating film 51 and the second insulating film 52. In a region outside the plurality of top wirings 30, the top insulating layer 50 covers the resistive film 8, the insulating region 7, and the forbidden regions 102 across a portion of the insulating layer 5. The top insulating layer 50 may cover an entire area of the region outside the plurality of top wirings 30 at the second end 5b of the insulating layer 5.

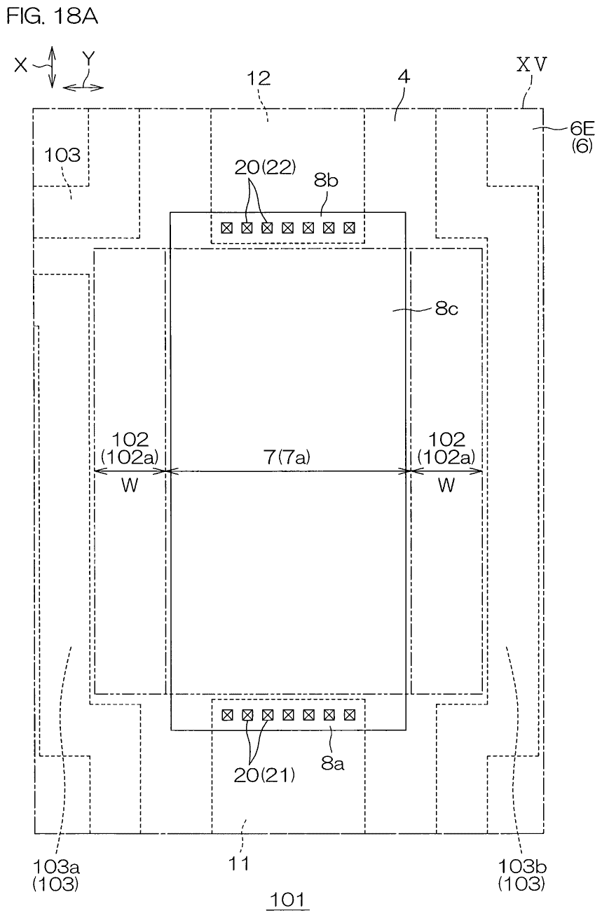

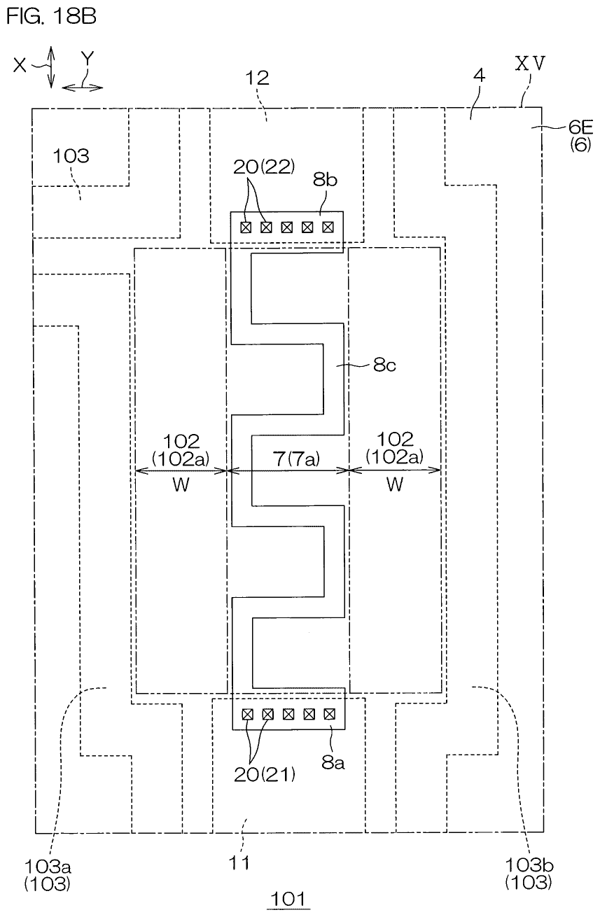

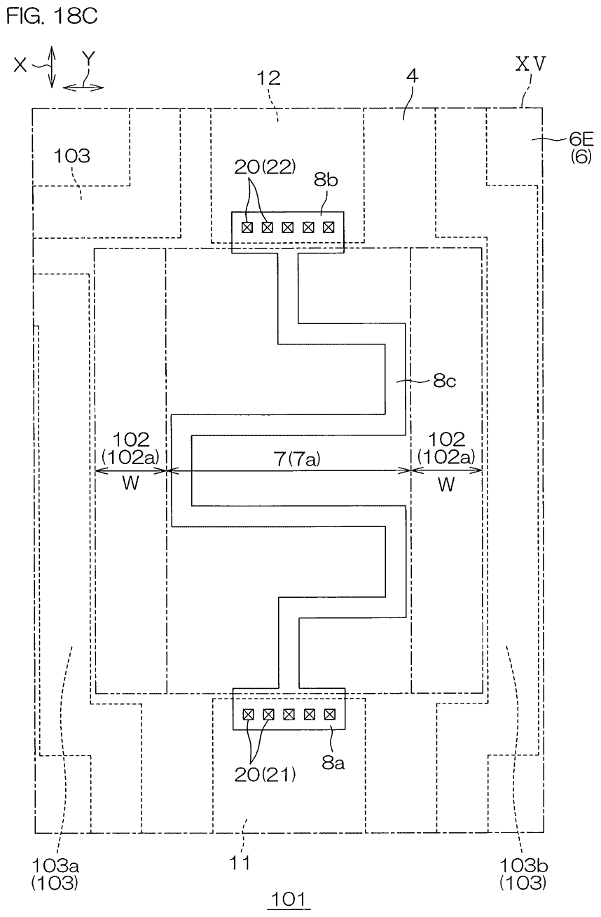

The resistive film 8 can have any of various patterns shown in FIG. 18A to FIG. 18C. FIG. 18A to FIG. 18C are enlarged views showing the region XV shown in FIG. 14 together with the resistive films 8 according to second to fourth patterns. In the following, structures corresponding to structures shown in FIG. 14 to FIG. 17 are provided with the same reference signs and description thereof shall be omitted.

Referring to FIG. 18A, in this embodiment, the resistive film 8 is formed to be wider than the first lower wiring 11 and the second lower wiring 12. That is, the first lower wiring 11 and the second lower wiring 12 are formed to be narrower than the resistive film 8.

Referring to FIG. 18B, in this embodiment, the resistive film 8 includes the main resistive body portion 8c that extends in a zigzag shape in the first direction X such as to meander to one side and another side in the second direction Y in a region between the first end portion 8a and the second end portion 8b in plan view. In this embodiment, the first lower wiring 11 and the second lower wiring 12 are formed to a width exceeding a meandering width of the resistive film 8. The meandering width of the resistive film 8 is a meandering range of the resistive film 8 along the second direction Y. That is, the first lower wiring 11 and the second lower wiring 12 are formed such that the resistive film 8 is included in the entire area of the facing region between the first lower wiring 11 and the second lower wiring 12 in plan view.

Referring to FIG. 18C, in this embodiment, the resistive film 8 includes the main resistive body portion 8c that extends in a zigzag shape in the first direction X such as to meander to one side and the other side in the second direction Y in the region between the first end portion 8a and the second end portion 8b in plan view. In this embodiment, the first lower wiring 11 and the second lower wiring 12 are formed to a width less than the meandering width of the resistive film 8. The meandering width of the resistive film 8 is the meandering range of the resistive film 8 along the second direction Y. That is, the first lower wiring 11 and the second lower wiring 12 are formed in a mode where portions of the resistive film 8 protrude from the facing region between the first lower wiring 11 and the second lower wiring 12 in plan view.

Referring to FIG. 18A to FIG. 18C, even in these embodiments, the insulating region 7 (insulator portion 7a) is formed across the entire area of the facing region between the first lower wiring 11 and the second lower wiring 12 inside the insulating layer 5 in plan view and sectional view. Also, the insulating region 7 is formed in the entire area of the portion in which the entire area of the main resistive body portion 8c overlaps with the first main surface 2a in plan view and sectional view. Also, the insulating region 7 is formed in the quadrilateral shape that includes the entirety of the main resistive body portion 8c on the basis of the portions of the peripheral edge of the main resistive body portion 8c that are positioned outermost in the second direction Y in plan view and sectional view.

Even in these embodiments, the forbidden regions 102 expand the insulator portion 7a in the direction (second direction Y) orthogonal to the facing direction (first direction X) of the first lower wiring 11 and the second lower wiring 12 and each have the above-described expansion width W with the peripheral edge of the resistive film 8 as the basis (zero point). In these embodiments, the forbidden regions 102 expand the insulating region 7 in quadrilateral shapes in plan view.

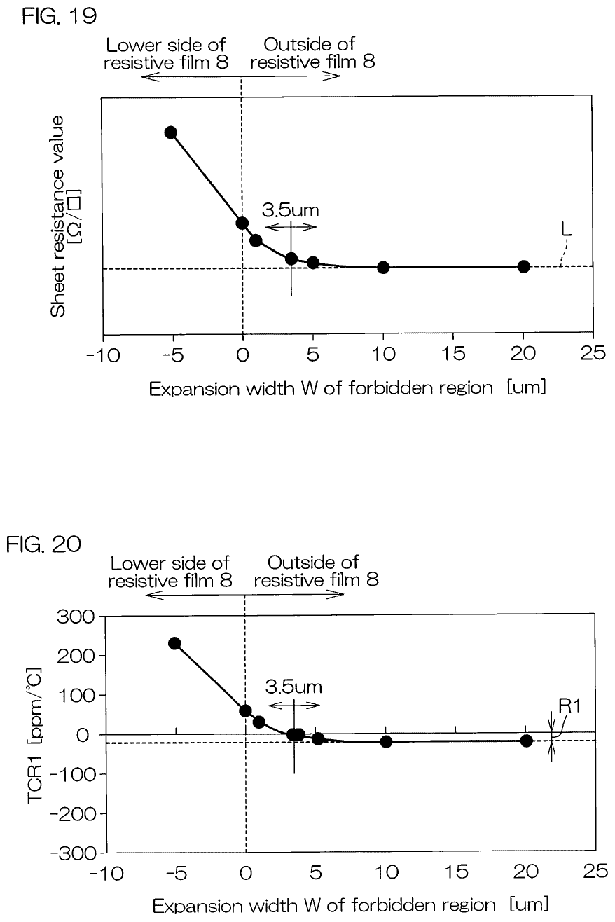

FIG. 19 is a graph showing the sheet resistance Rs of the resistive film 8 shown in FIG. 15. In FIG. 19, the ordinate shows the sheet resistance Rs [Ω/□] and the abscissa shows the expansion width W [μm] of each forbidden region 102. A sheet resistance characteristic SR when the expansion width W was changed and a design value line L of the sheet resistance Rs are shown in FIG. 19.

Here, the sheet resistance characteristic SR when the expansion width W was changed in a range of not less than −5 μm and not more than 20 μm is shown. A zero point of the expansion width W signifies the peripheral edge of the resistive film 8, a positive expansion width W signifies that a third wiring 103 is arranged away from the peripheral edge of the resistive film 8, and a negative expansion width W signifies that the third wiring 103 faces the resistive film 8 in a vertical direction. Here, the characteristic when one third wiring 103 is arranged on an interlayer insulating film 6 (third interlayer insulating film 6C) positioned below the resistive film 8 is shown.

Referring to the sheet resistance characteristic SR, it was confirmed that the sheet resistance Rs varies due to the expansion width W. Specifically, the sheet resistance Rs increased with decrease in the expansion width W and decreased with increase in the expansion width W. It was also confirmed that the sheet resistance characteristic SR has a tendency to saturate in a vicinity of the design value line L.

When the expansion width W was set in a negative range, the sheet resistance Rs exhibited a steep change rate of deviating from the design value line L with respect to a change rate of the expansion width W. An absolute value of a slope of a tangent to the sheet resistance characteristic SR takes on a maximum value when the expansion width W is in a negative range (−5 μm≤W<0 μm). On the other hand, when the expansion width W was set in a positive range, the sheet resistance Rs exhibited a gradual change rate with respect to the change rate of the expansion width W in the vicinity of the design value line L. The absolute value of the slope of the tangent to the sheet resistance characteristic SR takes on a minimum value when the expansion width W is in the positive range (0 μm≤W≤20 μm).

Specifically, the absolute value of the slope of the tangent to the sheet resistance characteristic SR changed from increasing to decreasing at the expansion width W of 3.5 μm as a boundary. When the expansion width W was not less than 3.5 μm, the sheet resistance characteristic SR (sheet resistance Rs) exhibited a tendency to converge toward the design value line L without diverging with increase in the expansion width W.

FIG. 20 is a graph showing the first order coefficient TCR1 of the TCR of the resistive film 8 shown in FIG. 15. In FIG. 20, the ordinate shows the first order coefficient TCR1 [ppm/° C.] and the abscissa shows the expansion width W [μm] of each forbidden region 102. A first order characteristic ST1 and a design range R1 of the first order characteristic ST1 are shown in FIG. 20. The design range R1 is not less than −25 ppm/° C. and not more than 0 ppm/° C. The measurement conditions are the same as in the case of the sheet resistance characteristic SR of FIG. 19.

Referring to the first order characteristic ST1, it was confirmed that the first order coefficient TCR1 varies due to the expansion width W. Specifically, the first order coefficient TCR1 increased with decrease in the expansion width W and decreased with increase in the expansion width W. It was also confirmed that the first order characteristic ST1 has a tendency to saturate in the design range R1.

When the expansion width W was set in the negative range, the first order coefficient TCR1 exhibited a steep change rate of deviating from the design range R1 with respect to the change rate of the expansion width W. An absolute value of a slope of a tangent to the first order characteristic ST1 takes on a maximum value when the expansion width W is in the negative range (−5 μm≤W<0 μm). On the other hand, when the expansion width W was set in the positive range, the first order coefficient TCR1 exhibited a gradual change rate with respect to the change rate of the expansion width W in a vicinity of the design range R1. The absolute value of the slope of the tangent to the first order characteristic ST1 takes on a minimum value when the expansion width W is in the positive range (0 μm≤W≤20 μm).

Specifically, the absolute value of the slope of the tangent to the first order characteristic ST1 changed from increasing to decreasing at the expansion width W of 3.5 μm as a boundary. When the expansion width W was not less than 3.5 μm, the first order characteristic ST1 (first order coefficient TCR1) exhibited a tendency to converge toward the design range R1 without diverging with increase in the expansion width W. When the expansion width W is not less than 3.5 μm, the first order coefficient TCR1 of the resistive film 8 is not less than −25 ppm/° C. and not more than 0 ppm/° C.

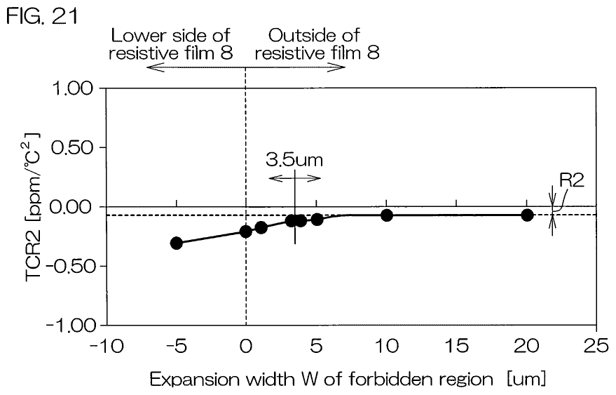

FIG. 21 is a graph showing the second order coefficient TCR2 of the TCR of the resistive film 8 shown in FIG. 15. In FIG. 21, the ordinate shows the second order coefficient TCR2 [ppm/° C.²] and the abscissa shows the expansion width W [μm] of each forbidden region 102. A second order characteristic ST2 and a design range R2 of the second order characteristic ST2 are shown in FIG. 21. The design range R2 is not less than −0.15 ppm/° C.² and not more than 0 ppm/° C.². The measurement conditions are the same as in the case of the sheet resistance characteristic SR of FIG. 19.

Referring to the second order characteristic ST2, it was confirmed that the second order coefficient TCR2 varies due to the expansion width W. Specifically, the second order coefficient TCR2 decreased with decrease in the expansion width W and increased with increase in the expansion width W. It was also confirmed that the second order coefficient TCR2 has a tendency to saturate in the design range R2.

When the expansion width W was set in the negative range, the second order coefficient TCR2 exhibited a steep change rate of deviating from the design range R2 with respect to the change rate of the expansion width W. An absolute value of a slope of a tangent to the second order characteristic ST2 takes on a maximum value when the expansion width W is in the negative range (−5 μm≤W<0 μm). On the other hand, when the expansion width W was set in the positive range, the second order coefficient TCR2 exhibited a gradual change rate with respect to the change rate of the expansion width W in a vicinity of the design range R2. The absolute value of the slope of the tangent to the second order characteristic ST2 takes on a minimum value when the expansion width W is in the positive range (0 μm≤W≤20 μm).

Specifically, the absolute value of the slope of the tangent to the second order characteristic ST2 changed from increasing to decreasing at the expansion width W of 3.5 μm as a boundary. When the expansion width W was not less than 3.5 μm, the second order characteristic ST2 (second order coefficient TCR2) exhibited a tendency to converge toward the design value range R2 without diverging with increase in the expansion width W. When the expansion width W is not less than 3.5 μm, the second order coefficient TCR2 of the resistive film 8 is not less than −0.15 ppm/° C.² and not more than 0 ppm/° C.².

From the results of FIG. 19 to FIG. 21, it can be understood that the electrical characteristics of the resistive film 8 are dependent on the expansion width W of each of the forbidden regions 102 (insulation expansion portions 102a) arranged between the resistive film 8 and the third wirings 103. This is because the electrical characteristics of the resistive film 8 are substantially established in the crystallizing step performed in the forming step of the resistive film 8. That is, in the crystallizing step, the base alloy film that is to be the base of the resistive film 8 is heated at the crystallization temperature. In this process, the greater the expansion width W inside the insulating layer 5, the lower a heat amount transferred to the third wirings 103 from the insulating region 7 and the forbidden regions 102 and the higher a heat storage effect in the insulating region 7 and the forbidden regions 102.

The heat amount applied to the base alloy film is thereby increased and the crystallization of the base alloy film is promoted. Consequently, the resistive film 8 of high precision is formed. Since this result is due to the heat storage effect of the insulating region 7 and the forbidden regions 102, there is no need to increase the crystallization temperature inside the chamber or to extend the crystallization time of the base alloy film. Therefore, if a functional device is formed in the semiconductor chip 2, generation of unnecessary heat loads on the functional device can be avoided.

As described above, the electronic component 101 includes the semiconductor chip 2, the insulating layer 5, the resistive film 8, the first lower wiring 11, the second lower wiring 12, and the insulating region 7. The semiconductor chip 2 has the first main surface 2a. The insulating layer 5 is laminated on the first main surface 2a. The resistive film 8 is arranged inside the insulating layer 5, includes the alloy crystal constituted of the metal element and the nonmetal element, and has the first end portion 8a at the one end and the second end portion 8b at the other end.

The first lower wiring 11 is interposed between the first main surface 2a and the first end portion 8a of the resistive film 8 inside the insulating layer 5. The second lower wiring 12 is separated from the first lower wiring 11 inside the insulating layer 5 and is interposed between the first main surface 2a and the second end portion 8b of the resistive film 8 inside the insulating layer 5. The insulating region 7 is demarcated in the region between the first lower wiring 11 and the second lower wiring 12 inside the insulating layer 5 and is formed of only the insulator portion 7a that is positioned within the thickness range between the first main surface 2a and the resistive film 8 in the insulating layer 5. With this structure, the reliability of the resistive film 8 can be improved.

The electronic component 101 preferably includes the forbidden regions 102 that expand the insulating region 7 to the ranges outside the resistive film 8 inside the insulating layer 5. The forbidden regions 102 each include the insulation expansion portion 102a that expands the insulator portion 7a of the insulating region 7 from the peripheral edge of the resistive film 8 to the range outside the resistive film 8. In this case, the electronic component 101 includes the plurality of third wirings 103 that are arranged inside the insulating layer 5. The plurality of third wirings 103 are arranged inside the insulating layer 5 away from the resistive film 8, the first lower wiring 11, and the second lower wiring 12 such as not to be positioned inside the insulating region 7 and the forbidden regions 102. With this structure, the reliability of the resistive film 8 can be improved in a structure in which the resistive film 8, the first lower wiring 11, the second lower wiring 12 and the plurality of third wirings 103 are arranged inside the insulating layer 5.

From another viewpoint, the electronic component 101 includes the semiconductor chip 2, the insulating layer 5, and the plurality of top wirings 30. The semiconductor chip 2 has the first main surface 2a. The insulating layer 5 is laminated on the first main surface 2a. The resistive film 8 is arranged inside the insulating layer 5 and includes the alloy crystal constituted of the metal element and the nonmetal element. The plurality of top wirings 30 are arranged in the region outside the resistive film 8 on the insulating layer 5 at intervals from the peripheral edge of the resistive film 8 such as not to overlap with the resistive film 8 in plan view. With this structure, stress generated in the resistive film 8 due to the plurality of top wirings 30 can be relaxed. Variations in the electrical characteristics of the resistive film 8 due to the plurality of top wirings 30 can thereby be suppressed. The reliability of the resistive film 8 can thus be improved.

In this structure, the electronic component 101 may include the first lower wiring 11, the second lower wiring 12, and the insulating region 7. The first lower wiring 11 is interposed between the first main surface 2a and the first end portion 8a of the resistive film 8 inside the insulating layer 5. The second lower wiring 12 is separated from the first lower wiring 11 inside the insulating layer 5 and is interposed between the first main surface 2a and the second end portion 8b of the resistive film 8 inside the insulating layer 5.

The insulating region 7 is demarcated in the region between the first lower wiring 11 and the second lower wiring 12 inside the insulating layer 5 and is formed of only the insulator portion 7a that is positioned within the thickness range between the first main surface 2a and the resistive film 8 in the insulating layer 5. In this case, the plurality of top wirings 30 are preferably arranged in the region outside the insulating region 7 in plan view. With this structure, the reliability of the resistive film 8 can be improved in a structure in which the resistive film 8, the first lower wiring 11, the second lower wiring 12, and the plurality of top wirings 30 are arranged.

The electronic component 101 preferably includes the forbidden regions 102 that expand the insulating region 7 to the ranges outside the resistive film 8 inside the insulating layer 5. The forbidden regions 102 each include the insulation expansion portion 102a that expands the insulator portion 7a of the insulating region 7 from the peripheral edge of the resistive film 8 to the range outside the resistive film 8. In this case, the plurality of top wirings 30 are preferably arranged in the region outside the insulating region 7 and the forbidden regions 102 in plan view. With this structure, the variations in the electrical characteristics of the resistive film 8 due to the plurality of top wirings 30 can be suppressed appropriately.

In this structure, the electronic component 101 may include at least one third wiring 103 that is arranged away from the resistive film 8, the first lower wiring 11 and the second lower wiring 12 inside the insulating layer 5. With this structure, the reliability of the resistive film 8 can be improved in a structure in which the resistive film 8, the first lower wiring 11, the second lower wiring 12, the third wiring 103, and the plurality of top wirings are arranged. The electronic component 101 may include the top insulating layer 50 that covers the insulating layer 5. Preferably, the top insulating layer 50 partially covers the top wirings 30 on the insulating layer 5 and covers the resistive film 8 across a portion of the insulating layer 5.

Preferably, at least one of the top wirings 30 is electrically connected to either or both of the semiconductor chip 2 (specifically, the functional device) and the resistive film 8. Preferably, at least one of the top wirings 30 is formed as the dummy top wiring 104 that is in the electrically floating state.

Configurations of the forbidden regions 102, the plurality of third wirings 103, and the plurality of top wirings 30 according to the sixth embodiment can also be applied to any one of the electronic components 61, 71, 81, and 91 of the second to fifth embodiments in addition to the first embodiment. In this case, the electronic components 1, 61, 71, 81, and 91 according to the first to fifth embodiments each include the insulating region 7, the forbidden regions 102, the plurality of third wirings 103, and the plurality of top wirings 30 and exhibit the same actions and effects as the actions and effects of the sixth embodiment.

The respective embodiments of the present invention can be implemented in yet other embodiments. With each of the embodiments described above, an example where the single resistive film 8 is arranged inside the insulating layer 5 was described. However, a plurality of the resistive films 8 may be arranged inside the insulating layer 5. In this case, the plurality of resistive films 8 are preferably arranged at intervals in the same layer. It is especially preferable for the plurality of resistive films 8 to exclusively occupy a main surface of an arbitrary one of the interlayer insulating film 6. The plurality of resistive films 8 may, in the insulating layer 5, be arranged inside a portion that covers the outside region 4. In plan view, the plurality of resistive films 8 may be arranged inside the same outside region 4 or may be arranged inside different outside regions 4. In this case, the insulating region 7 and the forbidden regions 102 are preferably provided for each of the plurality of resistive films 8.

With each of the embodiments described above, an example where the resistive film 8 is arranged inside a portion that covers the outside region 4 in the insulating layer 5 was described. However, the resistive film 8 may be arranged inside a portion that covers the device region 3 in the insulating layer 5. If a plurality of resistive films 8 are formed, the plurality of resistive films 8 may include one resistive film 8 that is arranged inside a portion that covers the outside region 4 in the insulating layer 5 and the other resistive film 8 that is arranged inside a portion that covers the device region 3 in the insulating layer 5. In this case, the insulating region 7 and the forbidden regions 102 are each preferably provided in the device region 3.

In each of the embodiments described above, a configuration not having the device region 3 may be adopted. That is, the electronic components 1, 61, 71, 81, 91, and 101 may each be a discrete component that includes only a single or a plurality of resistive films 8.

In each of the embodiments described above, an insulator chip constituted of glass or ceramic may be adopted in place of the semiconductor chip 2. The resistive film 8 according to each of the embodiments described above may be a fuse resistive film that fuses when a current not less than a rating flows. Specific embodiments of this case can be obtained by replacing “resistive film 8” by “fuse resistive film (8)” in the respective embodiments described above.

Features of the first to sixth embodiments described above may be combined with each other in arbitrary modes and an electronic component that includes at least two features among the features of the first to sixth embodiments at the same time may be adopted. That is, the features of the second embodiment may be combined with the features of the first embodiment. Also, the features of the third embodiment may be combined with any one of the features of the first and second embodiments. Also, the features of the fourth embodiment may be combined with any one of the features of the first to third embodiments. Also, the features of the fifth embodiment may be combined with any one of the features of the first to fourth embodiments. Also, the features of the sixth embodiment may be combined with any one of the features of the first to fifth embodiments.

Examples of features extracted from this description and the drawings are indicated below. The following [A1] to [A29] and [B1] to [B22] each provide an electronic component with which reliability of a resistive film that includes an alloy crystal constituted of a metal element and a nonmetal element can be improved.

[A1] An electronic component comprising: a chip that has a main surface; an insulating layer that is laminated at a thickness exceeding 2200 nm on the main surface and has a first end on the chip side and a second end on an opposite side to the chip; and a resistive film that is arranged inside the insulating layer such as not to be positioned within a thickness range of less than 2200 nm on a basis of the first end and includes an alloy crystal constituted of a metal element and a nonmetal element.

[A2] The electronic component according to A1, wherein the resistive film has a thickness of not less than 0.1 nm and not more than 100 nm.

[A3] The electronic component according to A1 or A2, further comprising: an insulating region that has only an insulator in a thickness direction of the insulating layer and is formed to a thickness of not less than 2200 nm inside the insulating layer; wherein the resistive film is arranged inside the insulating layer such as to cover the insulating region.

[A4] The electronic component according to any one of A1 to A3, further comprising: a plurality of wirings that are laminated and arranged in a thickness direction of the insulating layer within a thickness range between the main surface and the resistive film inside the insulating layer.

[A5] The electronic component according to A4, wherein the wirings are not arranged within a thickness range between the second end and the resistive film inside the insulating layer.

[A6] The electronic component according to any one of A1 to A5, wherein a thickness between the first end and the resistive film inside the insulating layer is not less than a thickness between the second end and the resistive film inside the insulating layer.

[A7] The electronic component according to any one of A1 to A6, wherein the insulating layer has a thickness exceeding 3100 nm, and the resistive film is arranged inside the insulating layer such as not to be positioned within a thickness range of less than 3100 nm on the basis of the first end.

[A8] The electronic component according to any one of A1 to A7, wherein the insulating layer has a laminated structure including not less than three layers of interlayer insulating films, and the resistive film is arranged on the interlayer insulating film of the third layer or higher.

[A9] The electronic component according to A8, wherein the insulating layer includes not less than four layers of the interlayer insulating films, and the resistive film is arranged on the interlayer insulating film of the fourth layer or higher.

[A10] The electronic component according to A8 or A9, wherein each of the interlayer insulating films has a thickness of not less than 100 nm and not more than 3000 nm.

[A11] The electronic component according to any one of A1 to A10, further comprising: a top wiring that is arranged on the second end.

[A12] The electronic component according to A11, further comprising: a top insulating layer that partially covers the top wiring.

[A13] The electronic component according to any one of A1 to A12, wherein a first order coefficient of a temperature coefficient of resistance of the resistive film is not less than −20 ppm/° C. and not more than +60 ppm/° C.

[A14] The electronic component according to A13, wherein the first order coefficient is not more than +25 ppm/° C.

[A15] The electronic component according to any one of A1 to A14, wherein a second order coefficient of a temperature coefficient of resistance of the resistive film is not less than −0.23 ppm/° C.² and not more than −0.08 ppm/° C.².

[A16] The electronic component according to A15, wherein the second order coefficient is not less than −0.16 ppm/° C.².

[A17] The electronic component according to any one of A1 to A16, wherein the resistive film includes at least one among a CrSi film, a CrSiN film, a CrSiO film, a TaN film, and a TiN film.

[A18] An electronic component comprising: a chip that has a main surface; an insulating layer that is laminated at a thickness exceeding 2200 nm on the main surface and has a first end on the chip side and a second end on an opposite side to the chip; an insulating region that has only an insulator in a thickness direction of the insulating layer and is formed to a thickness of not less than 2200 nm inside the insulating layer; and a resistive film that is arranged in a region between the second end and the insulating region inside the insulating layer such as to directly cover the insulating region and includes an alloy crystal constituted of a metal element and a nonmetal element.

[A19] The electronic component according to A18, further comprising: a first wiring that is arranged inside the insulating layer; and a second wiring that is arranged inside the insulating layer at an interval from the first wiring in plan view; wherein the insulating region is demarcated in a region between the first wiring and the second wiring in plan view and the resistive film is arranged inside the insulating layer such as to directly cover the insulating region and overlap with the first wiring and the second wiring in plan view.

[A20] The electronic component according to A19, further comprising: a first via electrode that is arranged between the resistive film and the first wiring inside the insulating layer; and a second via electrode that is arranged between the resistive film and the second wiring inside the insulating layer.

[A21] An electronic component comprising: a semiconductor chip that includes a main surface and has a first thermal conductivity; an insulating layer that is laminated at a thickness exceeding 3100 nm on the main surface, includes a first end on the semiconductor chip side and a second end on an opposite side to the semiconductor chip, and has a second thermal conductivity less than the first thermal conductivity; an insulating region that has only an insulator in a thickness direction of the insulating layer and is formed to a thickness of not less than 3100 nm in an arbitrary region inside the insulating layer; and a CrSi resistive film that is arranged inside the insulating layer at a thickness of not less than 0.1 nm and not more than 10 nm in a region between the second end and the insulating region such as to directly cover the insulating region.

[A22] The electronic component according to A21, wherein the CrSi resistive film has a thickness of not more than 5 nm.

[A23] The electronic component according to A21 or A22, wherein the CrSi resistive film has a thickness of not less than 1 nm.

[A24] The electronic component according to any one of A21 to A23, wherein the insulating layer has a laminated structure including not less than three layers of interlayer insulating films, and the CrSi resistive film is arranged on the interlayer insulating film of the third layer or higher.

[A25] The electronic component according to A24, wherein the insulating layer includes not less than four layers of the interlayer insulating films, and the CrSi resistive film is arranged on the interlayer insulating film of the fourth layer or higher.

[A26] The electronic component according to any one of A21 to A25, further comprising: a plurality of wirings that are laminated and arranged in a thickness direction of the insulating layer within a thickness range between the first end and the CrSi resistive film inside the insulating layer.

[A27] The electronic component according to A26, wherein the wirings are not arranged within a thickness range between the second end and the CrSi resistive film inside the insulating layer.

[A28] The electronic component according to A26, wherein the wirings are arranged within a thickness range between the second end and the CrSi resistive film inside the insulating layer.

[A29] The electronic component according to any one of A21 to A28, wherein a thickness between the first end and the CrSi resistive film inside the insulating layer is not less than a thickness between the second end and the CrSi resistive film inside the insulating layer.

[B1] An electronic component comprising: a chip that has a main surface; an insulating layer that is laminated on the main surface; a resistive film that is arranged inside the insulating layer, includes an alloy crystal constituted of a metal element and a nonmetal element, and has a first end portion on one side and a second end portion on another side; a first wiring that is interposed between the main surface and the first end portion inside the insulating layer; a second wiring that is separated from the first wiring and interposed between the main surface and the second end portion inside the insulating layer; and an insulating region that is demarcated in a region between the first wiring and the second wiring inside the insulating layer and is formed of only an insulator portion positioned within a thickness range between the main surface and the resistive film in the insulating layer.

[B2] The electronic component according to B1, further comprising: a forbidden region that includes an insulation expansion portion expanding the insulator portion to a range outside the resistive film from a peripheral edge of the resistive film and that expands the insulating region to the range outside the resistive film; and a plurality of third wirings that are arranged inside the insulating layer away from the resistive film, the first lower wiring and the second lower wiring such as not to be positioned inside the insulating region and the forbidden region.

[B3] The electronic component according to B2, wherein the forbidden region has an expansion width of not less than 2200 nm on a basis of the peripheral edge of the resistive film in plan view, and the plurality of third wirings are arranged not less than 2200 nm away from the peripheral edge of the resistive film in plan view.

[B4] The electronic component according to B3, wherein the insulating layer has a thickness exceeding 2200 nm, and the insulating region has a thickness of not less than 2200 nm.

[B5] The electronic component according to B3 or B4, wherein the expansion width is not less than 3.5 μm, and the plurality of third wirings are arranged not less than 3.5 μm away from the peripheral edge of the resistive film in plan view.

[B6] The electronic component according to any one of B3 to B5, wherein the expansion width is not more than 20 μm, and at least one of the third wirings is arranged within a range within 20 μm from the peripheral edge of the resistive film in plan view.

[B7] The electronic component according to any one of B2 to B6, wherein at least one of the third wirings is arranged in the same layer as the first wiring away from the first wiring, and at least one of the third wirings is arranged in a layer different from the first wiring.

[B8] The electronic component according to any one of B2 to B7, wherein at least one of the third wirings is electrically connected to either or both of the chip and the resistive film.

[B9] The electronic component according to any one of B2 to B8, wherein at least one of the third wirings is formed as a dummy wiring in an electrically floating state.

[B10] The electronic component according to any one of B2 to B9, wherein the plurality of third wirings are not arranged in a layer in which the resistive film is arranged.

[B11] The electronic component according to any one of B1 to B10, wherein the second wiring is arranged in the same layer as the first wiring.

[B12] The electronic component according to any one of B1 to B11, wherein the insulating layer has a laminated structure in which a plurality of interlayer insulating films are laminated, and the insulator portion has a laminated structure constituted of a portion of the plurality of interlayer insulating films.

[B13] The electronic component according to B12, wherein the insulating layer has a laminated structure including not less than three layers of the interlayer insulating films, and the resistive film is arranged on the interlayer insulating film of the third layer or higher.

[B14] The electronic component according to any one of B1 to B13, further comprising: a first via that is connected to the first end portion and the first wiring inside the insulating layer; and a second via that is connected to the second end portion and the second wiring inside the insulating layer.

[B15] The electronic component according to any one of B1 to B14, further comprising: a plurality of top wirings that are arranged on the insulating layer; and a top insulating layer that partially covers the top wirings.

[B16] An electronic component comprising: a chip that has a main surface; an insulating layer that is laminated on the main surface; a resistive film that is arranged inside the insulating layer and includes an alloy crystal constituted of a metal element and a nonmetal element; a plurality of top wirings that are arranged in a region outside the resistive film on the insulating layer at an interval from a peripheral edge of the resistive film such as not to overlap with the resistive film in plan view.

[B17] The electronic component according to B16, further comprising: a first wiring that is interposed between the main surface and one end portion of the resistive film inside the insulating layer; a second wiring that is interposed between the main surface and another end portion of the resistive film inside the insulating layer at an interval from the first wiring; and an insulating region that is demarcated in a region between the first wiring and the second wiring inside the insulating layer and is formed of only an insulator portion positioned within a thickness range between the main surface and the resistive film in the insulating layer; wherein the plurality of top wirings are arranged in a region outside the insulating region in plan view.

[B18] The electronic component according to B17, further comprising: a forbidden region that includes an insulation expansion portion expanding the insulator portion to a range outside the resistive film from a peripheral edge of the resistive film and that expands the insulating region to the range outside the resistive film; wherein the plurality of top wirings are arranged in a region outside the insulating region and the forbidden region in plan view.

[B19] The electronic component according to B18, further comprising: a third wiring that is arranged inside the insulating layer away from the resistive film, the first lower wiring and the second lower wiring such as not to be positioned inside the insulating region and the forbidden region.

[B20] The electronic component according to any one of B16 to B19, further comprising: a top insulating layer that partially covers the top wirings on the insulating layer and covers the resistive film across a portion of the insulating layer.

[B21] The electronic component according to any one of B16 to B20, wherein at least one of the top wirings is electrically connected to either or both of the chip and the resistive film.

[B22] The electronic component according to any one of B16 to B21, wherein at least one of the top wirings is formed as a dummy top wiring in an electrically floating state.

The above [A1] to [A29] and the above [B1] to [B22] can be combined with each other in any mode and an electronic component that includes at least two among the above [A1] to [A29] and the above [B1] to [B22] at the same time may be adopted.

While embodiments were described in detail above, these are merely specific examples used to clarify the technical contents and the present invention should not be interpreted as being limited to these specific examples and the scope of the present invention is limited only by the appended claims.

What is claimed is:

1. An electronic component comprising:
a chip that has a main surface;
an insulating layer that is laminated at a thickness exceeding 2200 nm on the main surface and has a first end on the chip side and a second end on an opposite side to the chip; and
a resistive film that is arranged inside the insulating layer such as not to be positioned within a thickness range of less than 2200 nm on a basis of the first end and includes an alloy crystal constituted of a metal element and a nonmetal element.

2. The electronic component according to claim 1,
wherein the resistive film has a thickness of not less than 0.1 nm and not more than 100 nm.

3. The electronic component according to claim 1, further comprising:
an insulating region that has only an insulator in a thickness direction of the insulating layer and is formed to a thickness of not less than 2200 nm inside the insulating layer;
wherein the resistive film is arranged inside the insulating layer such as to cover the insulating region.

4. The electronic component according to claim 1, further comprising:
a plurality of wirings that are laminated and arranged in a thickness direction of the insulating layer within a thickness range between the main surface and the resistive film inside the insulating layer.

5. The electronic component according to claim 4,
wherein the wirings are not arranged within a thickness range between the second end and the resistive film inside the insulating layer.

6. The electronic component according to claim 1,
wherein a thickness between the first end and the resistive film inside the insulating layer is not less than a thickness between the second end and the resistive film inside the insulating layer.

7. The electronic component according to claim 1,
wherein the insulating layer has a thickness exceeding 3100 nm, and
the resistive film is arranged inside the insulating layer such as not to be positioned within a thickness range of less than 3100 nm on the basis of the first end.

8. The electronic component according to claim 1,
wherein the insulating layer has a laminated structure including not less than three layers of interlayer insulating films, and
the resistive film is arranged on the interlayer insulating film of the third layer or higher.

9. The electronic component according to claim 8,
wherein the insulating layer includes not less than four layers of the interlayer insulating films, and
the resistive film is arranged on the interlayer insulating film of the fourth layer or higher.

10. The electronic component according to claim 8,
wherein each of the interlayer insulating films has a thickness of not less than 100 nm and not more than 3000 nm.

11. The electronic component according to claim 1, further comprising:
a top wiring that is arranged on the second end.

12. The electronic component according to claim 11, further comprising:
a top insulating layer that partially covers the top wiring.

13. The electronic component according to claim 1,
wherein a first order coefficient of a temperature coefficient of resistance of the resistive film is not less than −20 ppm/° C. and not more than +60 ppm/° C.

14. The electronic component according to claim 13,
wherein the first order coefficient is not more than +25 ppm/° C.

15. The electronic component according to claim 1,
wherein a second order coefficient of a temperature coefficient of resistance of the resistive film is not less than −0.23 ppm/° C.² and not more than −0.08 ppm/° C.².

16. The electronic component according to claim 15,
wherein the second order coefficient is not less than −0.16 ppm/° C.².

17. The electronic component according to claim 1,
wherein the resistive film includes at least one among a CrSi film, a CrSiN film, a CrSiO film, a TaN film, and a TiN film.

18. An electronic component comprising:
a chip that has a main surface;
an insulating layer that is laminated at a thickness exceeding 2200 nm on the main surface and has a first end on the chip side and a second end on an opposite side to the chip;
an insulating region that has only an insulator in a thickness direction of the insulating layer and is formed to a thickness of not less than 2200 nm inside the insulating layer; and
a resistive film that is arranged in a region between the second end and the insulating region inside the insulating layer such as to directly cover the insulating region and includes an alloy crystal constituted of a metal element and a nonmetal element.

19. The electronic component according to claim 18, further comprising:
a first wiring that is arranged inside the insulating layer; and
a second wiring that is arranged at an interval from the first wiring in plan view inside the insulating layer;
wherein the insulating region is demarcated in a region between the first wiring and the second wiring in plan view, and
the resistive film is arranged inside the insulating layer such as to directly cover the insulating region and overlap with the first wiring and the second wiring in plan view.

20. The electronic component according to claim 19, further comprising:
a first via electrode that is arranged between the resistive film and the first wiring inside the insulating layer; and
a second via electrode that is arranged between the resistive film and the second wiring inside the insulating layer.
